(19) United States
(12) Patent Application Publication
(10) Pub. No.: US 2024/0349478 A1
(43) Pub. Date: Oct. 17, 2024

(54) METHODS OF FORMING MICROELECTRONIC DEVICES, AND RELATED MICROELECTRONIC DEVICES, MEMORY DEVICES, AND ELECTRONIC SYSTEMS

(71) Applicant: Micron Technology, Inc., Boise, ID (US)

(72) Inventors: Fatma Arzum Simsek-Ege, Boise, ID (US); Scott L. Light, Boise, ID (US); Efe S. Ege, Boise, ID (US); Chunhua Yao, Boise, ID (US)

(21) Appl. No.: 18/619,000

(22) Filed: Mar. 27, 2024

Related U.S. Application Data
(60) Provisional application No. 63/496,263, filed on Apr. 14, 2023.

(51) Int. Cl. H10B 12/00

(52) U.S. Cl. CPC H10B 12/0335; H10B 12/315; H10B 12/482; H10B 12/485

(57) ABSTRACT

A method of forming a microelectronic device includes forming a first dielectric stack over a semiconductor base structure including pillar structures separated by filled isolation trenches. Digit line contacts are formed to partially vertically extend through the first dielectric stack and into digit line contact regions of the pillar structures. Digit lines are formed over and in contact with the digit line contacts, and partially vertically extend through the first dielectric stack. A second dielectric stack is formed over the digit lines and the first dielectric stack. Storage node contacts are formed to vertically extend partially through the second dielectric stack, completely through the first dielectric stack, and into storage node contact regions of the pillar structures. Redistribution layer structures are formed over and in contact with the storage node contacts, and partially vertically extend through the second dielectric stack. Microelectronic devices, memory devices, and electronic systems are also described.

### CROSS-REFERENCE TO RELATED APPLICATION

This application claims the benefit under 35 U.S.C. § 119 (e) of U.S. Provisional Patent Application Ser. No. 63/496,263, filed Apr. 14, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

A relatively common microelectronic device is a memory device. A memory device may include a memory array having a number of memory cells arranged in a grid pattern. One type of memory cell is a dynamic random access memory (DRAM). In the simplest design configuration, a DRAM cell includes one access device, such as a transistor, and one storage device, such as a capacitor. Modern applications for memory devices can utilize vast numbers of DRAM unit cells, arranged in an array of rows and columns. The DRAM cells are electrically accessible through digit lines and word lines arranged along the rows and columns of the array.

Reducing the dimensions and spacing of memory device features places ever increasing demands on the methods used to form the memory device features. For example, DRAM device manufacturers face a tremendous challenge on reducing the DRAM cell area as feature spacing decreases to accommodate increased feature density. Conventional approaches to reducing spacing between neighboring digit lines often reduce margin for error (e.g., alignment errors), and can result in undesirable shorts and/or undesirable capacitive coupling effects without complex and time-consuming feature alignment methodologies.

### BRIEF DESCRIPTION OF THE DRAWINGS

FIGS. 1A through 11B are simplified, partial longitudinal cross-sectional views (FIGS. 1A, 2A, 3A, 4A, 5A, 6A, 7A, 8A, 9A, 10A, and 11A) and simplified, partial top-down views (FIGS. 1B, 2B, 3B, 4B, 5B, 6B, 7B, 8B, 9B, 10B, and 11B) of a microelectronic device structure at different processing stages of a method of forming a microelectronic device, in accordance with embodiments of the disclosure.

FIG. 12 is a functional block diagram of a memory device, in accordance with an embodiment of the disclosure.

FIG. 13 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{y}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

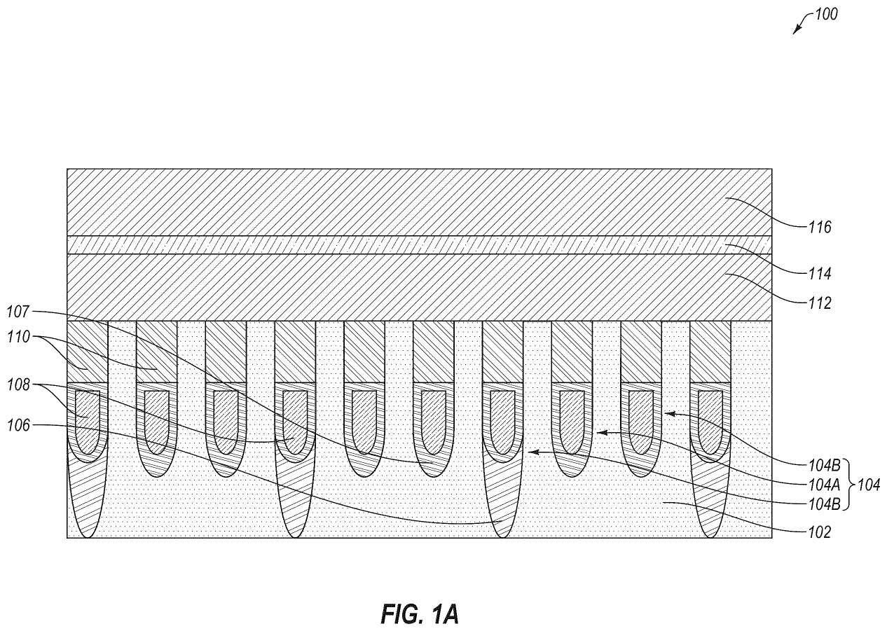

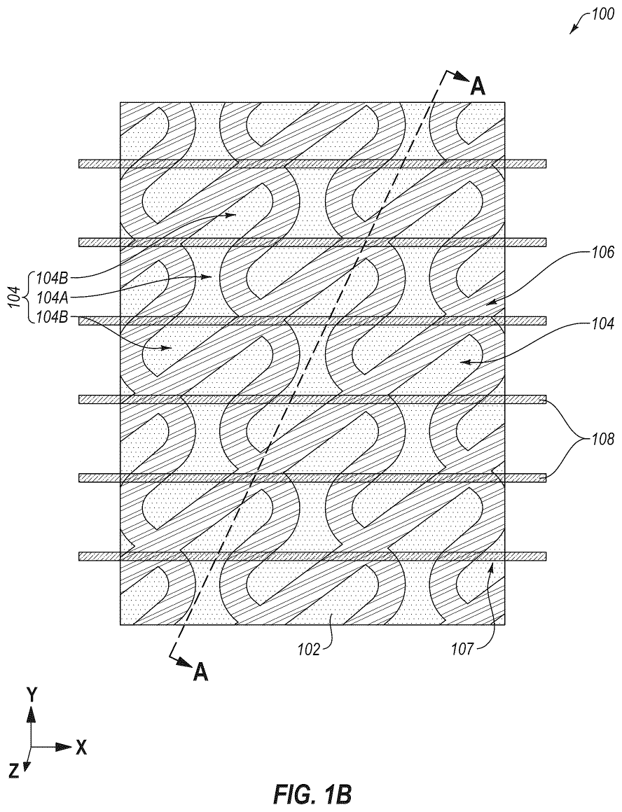

FIGS. 1A through 11B are simplified, partial longitudinal cross-sectional views (FIGS. 1A, 2A, 3A, 4A, 5A, 6A, 7A, 8A, 9A, 10A, and 11A) and simplified, partial top-down views (FIGS. 1B, 2B, 3B, 4B, 5B, 6B, 7B, 8B, 9B, 10B, and 11B) of a microelectronic device structure (e.g., a memory device structure, such as a DRAM structure) at different processing stages of a method of forming a microelectronic device (e.g., a memory device, such as a DRAM device), in accordance with embodiments of the disclosure. With the description provided below, it will be readily apparent to one of ordinary skill in the art that the methods described herein may be used to form various microelectronic devices, such as to form microelectronic devices where three-dimensional (3D) scaling is advantageous.

Referring to FIG. 1A, a microelectronic device structure 100 may be formed to include a base semiconductor structure 102, and filled trenches 106 vertically extending into the base semiconductor structure 102. The filled trenches 106 horizontally surround and at least partially define pillar structures 104 of the base semiconductor structure 102. The microelectronic device structure 100 may further include additional filled trenches 107 embedded within and horizontally extending through the pillar structures 104 and the filled trenches 106, word line structures 108 (e.g., access line structures, word lines, access lines) within the additional filled trenches 107, and insulative line structures 110 (e.g., word line capping structures, access line capping structures) within the additional filled trenches 107 and vertically overlying the word line structures 108. In addition, the microelectronic device structure 100 may include a first dielectric material 112 vertically overlying the base semiconductor structure 102, a second dielectric material 114 vertically overlying the first dielectric material 112, and a third dielectric material 116 vertically overlying the second dielectric material 114. The first dielectric material 112, the second dielectric material 114, and the third dielectric material 116 may together form a first dielectric stack (e.g., a first stack of dielectric materials, a first dielectric stack structure) over the pillar structures 104, the filled trenches 106, and the additional filled trenches 107. FIG. 1B is a top-down view of microelectronic device structure 100 at the processing stage shown in FIG. 1A, wherein a line A-A corresponds to the longitudinal cross-section of the microelectronic device structure 100 depicted in FIG. 1A. For clarity in understanding the drawings and related description, some features (e.g., structures, materials, regions) of the microelectronic device structure 100 at the processing stage of FIGS. 1A and 1B that are depicted in FIG. 1A are not depicted in FIG. 1B, and vice versa. For example, to better illustrate the pillar structures 104, the filled trenches 106, and the word line structures 108 in FIG. 1B, each of the insulative line structures 110, the first dielectric material 112, the second dielectric material 114, and the third dielectric material 116 depicted in FIG. 1A are omitted from (i.e., are not depicted in) FIG. 1B. However, it will be understood that any feature depicted in at least one of FIGS. 1A and 1B may be included in the microelectronic device structure 100 at the processing stage of FIGS. 1A and 1B.

The base semiconductor structure 102 comprises a base material or construction upon which additional features (e.g., materials, structures, devices) of the microelectronic device structure 100 are formed. The base semiconductor structure 102 may comprise a semiconductor structure (e.g., a semiconductor wafer), or a base semiconductor material on a supporting structure. For example, the base semiconductor structure 102 may comprise a conventional silicon substrate (e.g., a conventional silicon wafer), or another bulk substrate comprising a semiconductor material. In some embodiments, the base semiconductor structure 102 comprises a silicon wafer. The base semiconductor structure 102 may include one or more layers, structures, and/or regions formed therein and/or thereon.

The pillar structures 104 may individually vertically extend (e.g., project) from a relatively lower portion of the base semiconductor structure 102 that horizontally extends across and between the pillar structures 104. The pillar structures 104 may be formed of and include semiconductor material (e.g., silicon, such as polycrystalline silicon) of the base semiconductor structure 102, and may be considered so-called “active” regions of the base semiconductor structure 102. The filled trenches 106 may be horizontally interposed between the pillar structures 104 of the base semiconductor structure 102, as described in further detail below. In addition, the pillar structures 104 of the base semiconductor structure 102 may vertically extend beyond upper boundaries of the word line structures 108, and at least to upper boundaries of the insulative line structures 110, as also described in further detail below.

Referring collectively to FIGS. 1A and 1B, the pillar structures 104 may individually exhibit an elongate (e.g., non-circular, non-square) horizontal cross-sectional shape (see FIG. 1B) at least partially defined by the horizontal cross-sectional shapes of the filled trenches 106 horizontally adjacent thereto. The pillar structures 104 may individually include an upper surface, opposing horizontal ends, and opposing horizontal sides extending form and between the opposing ends. Intersections of the opposing horizontal ends of an individual pillar structure 104 with the opposing horizontal sides of the pillar structure 104 may define horizontal corners of the pillar structure 104. As shown in FIG. 1A, the upper surfaces of the pillar structures 104 may be substantially coplanar with one another. In addition, an individual pillar structure 104 may include a digit line contact region 104A (e.g., bit line contact region) and storage node contact regions 104B (e.g., cell contact regions). As shown in FIG. 1B, the storage node contact regions 104B of the pillar structure 104 may be located proximate the opposing horizontal ends of the pillar structure 104, and the digit line contact region 104A may be horizontally interposed between the storage node contact regions 104B. The digit line contact region 104A may be positioned at or proximate a horizontal center of the pillar structure 104. In some embodiments, as depicted in FIG. 1B, the digit line contact region 104A of an individual pillar structure 104 is horizontally narrower (e.g., in the X-direction) than each of the storage node contact regions 104B of the pillar structure 104. The digit line contact region 104A and the storage node contact regions 104B of an individually pillar structure 104 may be separated from one another by a pair of the additional filled trenches 107, as described in further detail below. Furthermore, as shown in FIG. 1B, for two (2) of pillar structures 104 horizontally neighboring one another in the X-direction, the digit line contact region 104A of one of the pillar structures 104 may horizontally overlap, in the Y-direction, one of the storage node contact regions 104B of the other of the pillar structures 104.

With continued reference to FIGS. 1A and 1B, the pillar structures 104 are separated from one another by the filled trenches 106. The filled trenches 106 may, for example, be employed as shallow trench isolation (STI) structures within the base semiconductor structure 102. A vertical height (e.g., in the Z-direction) of the pillar structures 104 may correspond to (e.g., be the same as) as vertical height (e.g., in the Z-direction) of the filled trenches 106. As shown in FIG. 1B, some of the filled trenches 106 may be positioned adjacent the opposing horizontal ends of the pillar structures 104, and may horizontally extend in substantially linear paths; and others of the filled trenches 106 may be positioned adjacent the opposing horizontal sides of the pillar structures 104, and may horizontally extend in substantially non-linear paths (e.g., wavy paths). The some of the filled trenches 106 may horizontally intersect the others of the filled trenches 106 at or proximate horizontal corners of the pillar structures 104.

The filled trenches 106 may comprise trenches in the base semiconductor structure 102 filled, at least in part, with at least one insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the insulative material of the filled trenches 106 comprises SiOₓ (e.g., SiO₂). The insulative material of the filled trenches 106 may be substantially homogeneous, or the insulative material of the filled trenches 106 may be heterogeneous.

Still referring to FIGS. 1A and 1B, the additional filled trenches 107 may vertically overlap and horizontally extend through the pillar structures 104 and the filled trenches 106. In some embodiments, the additional filled trenches 107 horizontally extend in substantially linear paths. For example, the referring to FIG. 1B, the additional filled trenches 107 may horizontally extend in parallel with one another in the X-direction, as represented by the paths of the word line structures 108 depicted in FIG. 1B (since the word line structures 108 are positioned within horizontal areas of the additional filled trenches 107). As used herein, the term “parallel” means substantially parallel.

Within a horizontal area of an individual pillar structure 104, portions of two (2) of the additional filled trenches 107 may be separate (e.g., isolate) the storage node contact regions 104B of pillar structure 104 from the digit line contact region 104A of the pillar structure 104. The portions of the two (2) of the additional filled trenches 107 may be horizontally interposed between the digit line contact region 104A and the storage node contact regions 104B, and may partially define horizontal boundaries of the digit line contact region 104A and the storage node contact regions 104B.

As shown in FIG. 1A, the additional filled trenches 107 may be formed to vertically extend to and terminate at different depths (e.g., vertical elevations) within the base semiconductor structure 102 than the filled trenches 106. For example, the additional filled trenches 107 may vertically extend to and terminate at relatively shallower depths within the base semiconductor structure 102 than the filled trenches 106. In addition, each of the additional filled trenches 107 may be formed to exhibit substantially the same horizontal dimension(s) and substantially the same horizontal cross-sectional shape(s) as each other of the additional filled trenches 107; or at least one of the additional filled trenches 107 may be formed to exhibit one or more of different horizontal dimension(s) (e.g., relatively larger horizontal dimension(s), relatively smaller horizontal dimension(s)) and different horizontal cross-sectional shape(s) than at least one other of the additional filled trenches 107.

The additional filled trenches 107 may comprise trenches in the pillar structures 104 and the filled trenches 106 filled, in part, with at least one additional insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. A material composition of the additional insulative material of the additional filled trenches 107 may be substantially the same as a material composition of the insulative material of the filled trenches 106, or the material composition of the additional insulative material of the additional filled trenches 107 may be different than the material composition of the insulative material of the filled trenches 106. In some embodiments, the additional insulative material of the additional filled trenches 107 comprises SiOₓ (e.g., SiO₂). The additional insulative material of the additional filled trenches 107 may be substantially homogeneous, or the additional insulative material of the additional filled trenches 107 may be heterogeneous.

With continued reference to FIGS. 1A and 1B, the word line structures 108 may be formed within the additional filled trenches 107. In some embodiments, the word line structures 108 are employed as word line structures (e.g., access line structures) of the microelectronic device structure 100. As shown in FIG. 1B, the word line structures 108 may exhibit horizontally elongate shapes extending in parallel in the X-direction (FIG. 1B). An individual word line structure 108 may continuously horizontally extend across (and be shared by) multiple of the pillar structures 104. Within a horizontal area of an individual pillar structure 104, portions of two (2) of the word line structures 108 may be horizontally interposed between the digit line contact region 104A of the pillar structure 104 and the storage node contact regions 104B of the pillar structure 104. As shown in FIG. 1A, uppermost surfaces of the word line structures 108 may vertically underlie uppermost surfaces of the pillar structures 104.

The word line structures 108 may individually be formed of and include conductive material, such as one or more of at least one metal, at least one an alloy, at least one conductive metal-containing material, and at least one conductively doped semiconductor material. In some embodiments, the word line structures 108 are individually formed of and include tungsten (W). The word line structures 108 may each be substantially homogeneous, or more or more of the word line structures 108 may individually be heterogeneous.

As shown in FIG. 1A, additional insulative material of the additional filled trenches 107 may be interposed between the word line structures 108 and the pillar structures 104. The additional insulative material of the additional filled trenches 107 may substantially cover at least side surfaces and bottom surfaces of the word line structures 108. The additional insulative material of the additional filled trenches 107 may intervene between the word line structures 108 and the digit line contact regions 104A and the storage node contact regions 104B of the pillar structures 104. In some embodiments, the additional insulative material of the additional filled trenches 107 is employed as a gate dielectric material (e.g., a gate oxide material) for access devices (e.g., transistors) formed to include the pillar structures 104 and the word line structures 108.

Referring to FIG. 1A, the insulative line structures 110 may be formed within the additional filled trenches 107, and may be vertically interposed between the word line structures 108 and the first dielectric material 112. In some embodiments, the insulative line structures 110 are employed as word line capping structures (e.g., access line capping structures) of the microelectronic device structure 100. The insulative line structures 110 may exhibit horizontally elongate shapes extending in parallel in the X-direction (FIG. 1B) and corresponding to the horizontally elongate shapes of the word line structures 108 vertically thereunder. An individual insulative line structures 110 may continuously horizontally extend across multiple of the pillar structures 104. Within a horizontal area of an individual pillar structure 104, portions of two (2) of the insulative line structures 110 may be horizontally interposed between the digit line contact region 104A of the pillar structure 104 and the storage node contact regions 104B of the pillar structure 104. As shown in FIG. 1A, uppermost surfaces of the insulative line structures 110 may be substantially coplanar with uppermost surfaces of the pillar structures 104.

The insulative line structures 110 may individually be formed of insulative material, such as one or more of a dielectric oxide material (e.g., silicon dioxide; phosphosilicate glass; borosilicate glass; borophosphosilicate glass; fluorosilicate glass; aluminum oxide; a combination thereof), a dielectric nitride material (e.g., SiN_{y}), a dielectric an oxynitride material (e.g., SiOₓN_{y}), a dielectric carbonitride material (e.g., SiCₓN_{y}), and a dielectric carboxynitride material (e.g., SiOₓC_{y}N_{z}), and amorphous carbon. In some embodiments, the insulative line structures 110 are individually formed of and include silicon nitride (e.g., SiN_{y}, such as Si₃N₄). In additional embodiments, the insulative line structures 110 are individually formed of and include silicon oxide (e.g., SiOₓ, such as SiO₂). The insulative line structures 110 may individually be substantially homogeneous, or one or more of the insulative line structures 110 may be heterogeneous.

Still referring to FIG. 1A, the first dielectric material 112 may be formed on or over the pillar structures 104, the filled trenches 106, and the additional filled trenches 107 (including the insulative line structures 110 therein). The first dielectric material 112 may substantially cover uppermost surfaces of the pillar structures 104, the filled trenches 106, and the insulative line structures 110 within the additional filled trenches 107. The first dielectric material 112 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the first dielectric material 112 is formed of and includes dielectric oxide material (e.g., SiOₓ, such as SiO₂). The first dielectric material 112 may be formed to have a desirable vertical height (e.g., in the Z-direction), such as a vertical height within a range of from about 5 nanometers (nm) to about 15 nm, from about 7 nm to about 12 nm, or about 10 nm.

The second dielectric material 114 may be formed on or over the first dielectric material 112. The second dielectric material 114 may substantially cover an uppermost surface of the first dielectric material 112. A material composition of the second dielectric material 114 is different than a material composition of the first dielectric material 112. The material composition of the second dielectric material 114 may be selected such that the second dielectric material 114 has etch selectivity relative to the first dielectric material 112. For example, if the first dielectric material 112 is formed of and includes dielectric oxide material (e.g., SiOₓ, such as SiO₂), the second dielectric material 114 may not be formed of and include dielectric oxide material. In some embodiments, the second dielectric material 114 is formed of and includes dielectric nitride material (e.g., SiN_{y}, such as Si₃N₄). The second dielectric material 114 may be formed to have a desirable vertical height (e.g., in the Z-direction), such as a vertical height within a range of from about 1 nm to about 10 nm, from about 3 nm to about 7 nm, or about 5 nm.

The third dielectric material 116 may be formed on or over the second dielectric material 114. The third dielectric material 116 may substantially cover an uppermost surface of the second dielectric material 114. A material composition of the third dielectric material 116 is different than the material composition of the second dielectric material 114. The material composition of the third dielectric material 116 may be substantially the same as or may be different than the material composition of the first dielectric material 112. The material composition of the third dielectric material 116 may be selected such that the second dielectric material 114 has etch selectivity relative to the third dielectric material 116. For example, if the second dielectric material 114 is formed of and includes dielectric nitride material (e.g., SiN_{y}, such as Si₃N₄), the third dielectric material 116 may not be formed of and include dielectric nitride material. In some embodiments, the third dielectric material 116 is formed of and includes dielectric oxide material (e.g., SiOₓ, such as SiO₂). The third dielectric material 116 may be formed to have a desirable vertical height (e.g., in the Z-direction), such as a vertical height within a range of from about 25 nm to about 35 nm, from about 27 nm to about 32 nm, or about 30 nm.

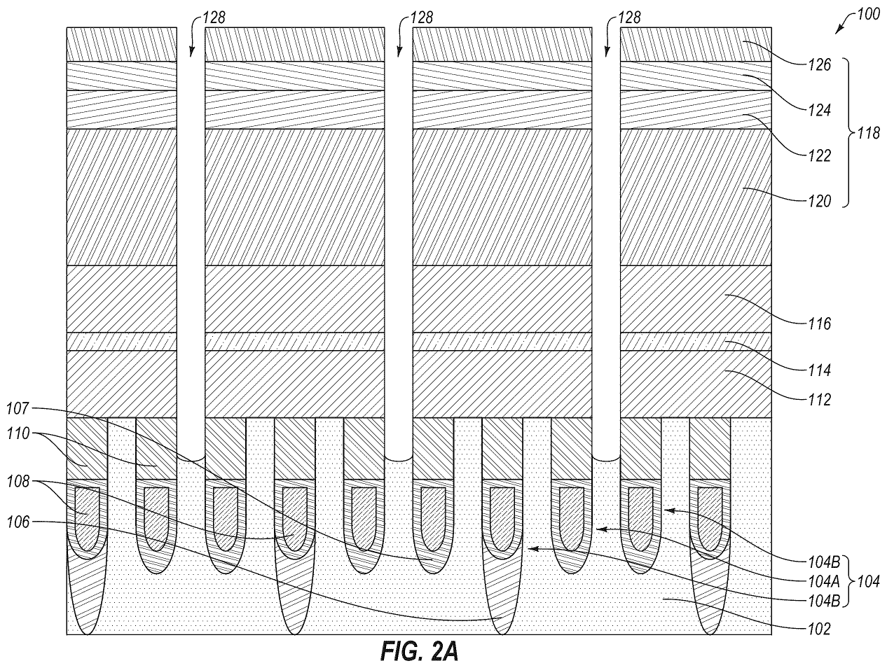

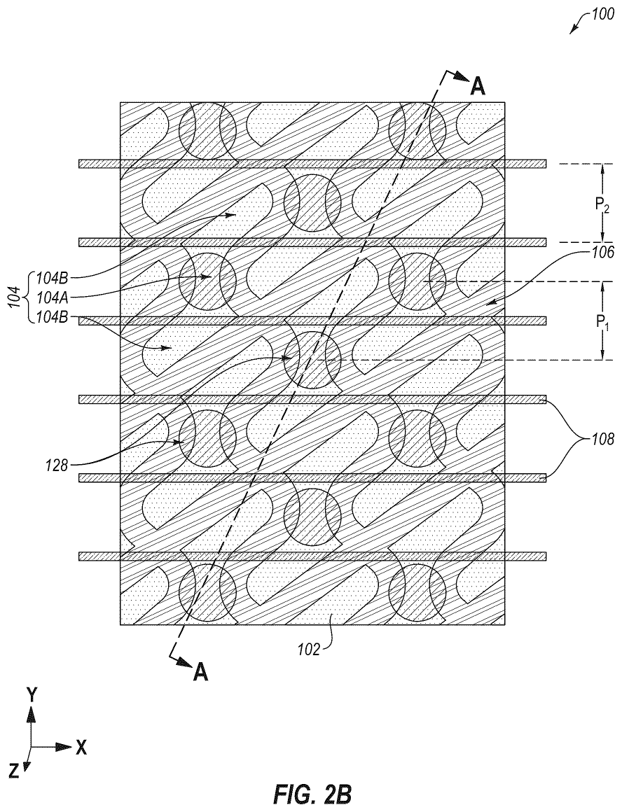

Referring next to FIG. 2A, a first hardmask structure 118 may be formed on or over the third dielectric material 116, and initial digit line contact openings 128 may be formed to vertically extend through the first hardmask structure 118, the third dielectric material 116, the second dielectric material 114, and the first dielectric material 112 and into the pillar structures 104 of the base semiconductor structure 102. As described in further detail below, the initial digit line contact openings 128 may be formed to horizontally overlap the digit line contact regions 104A of the pillar structures 104. FIG. 2B is a top-down view of the microelectronic device structure 100 at the processing stage shown in FIG. 2A, wherein the line A-A corresponds to the longitudinal cross-section of the microelectronic device structure 100 depicted in FIG. 2A. For clarity in understanding the drawings and related description, some features (e.g., structures, materials, regions) of the microelectronic device structure 100 at the processing stage of FIGS. 2A and 2B that are depicted in FIG. 2A are not depicted in FIG. 2B, and vice versa. However, it will be understood that any feature depicted in at least one of FIGS. 2A and 2B may be included in the microelectronic device structure 100 at the processing stage of FIGS. 2A and 2B.

The first hardmask structure 118 may be formed to comprise a multi-layered lithography stack. For example, as shown in FIG. 2A, the first hardmask structure 118 may be formed to include a first underlayer (UL) material 120 on or over the third dielectric material 116, a first developable anti-reflective coating (DARC) material 122 on or over the first UL material 120, a first resist adhesion layer (RAL) material 124 on or over the first DARC material 122, and a first extreme ultraviolet (EUV) resist material 126 on or over the first RAL material 124. The foregoing features of the first hardmask structure 118 are described in further detail below.

The first UL material 120 of the first hardmask structure 118 may be formed of and include at least one material having desirable adhesion and planarization characteristics. A material composition of the first UL material 120 may be selected, at least in part, based on material compositions of the third dielectric material 116 and the first DARC material 122. The first UL material 120 may, for example, be formed of and include one or more of an organic material (e.g., an organic spin-on material), an inorganic oxide material, and an inorganic nitride material. In some embodiments, the first UL material 120 is formed of and includes a carbon-containing material (e.g., amorphous carbon). The first UL material 120 may be formed to have a desirable vertical height (e.g., in the Z-direction), such as a vertical height within a range of from about 50 nm to about 100 nm, from about 60 nm to about 90 nm, from about 75 nm to about 85 nm, or about 80 nm.

The first DARC material 122 may be formed of and include at least one material formulated to reduce reflections and improve pattern transfer during lithography processes. In some embodiments, the first DARC material 122 is formed of and includes an Si-rich DARC material including a relatively high concentration of silicon. By way of non-limiting example, the first DARC material 122 may be formed of and include one or more of an SiOₓ-based DARC material including a relatively high concentration of SiOₓ; an SiN_{y}-based DARC material including a relatively high concentration of SiN_{y}; a SiCOH-based DARC material including a combination of silicon, carbon, oxygen, and hydrogen; and/or a SiCN-based DARC including a combination of silicon, carbon, and nitrogen. The first DARC material 122 may be formed to have a desirable vertical height (e.g., in the Z-direction), such as a vertical height within a range of from about 10 nm to about 25 nm, from about 10 nm to about 15 nm, or about 10 nm.

The first RAL material 124 may be formed of and include at least one material formulated to enhance adhesion of the first EUV resist material 126 to the first DARC material 122. A material composition of the first RAL material 124 may be selected, at least in part, based on material compositions of the first EUV resist material 126 and the first DARC material 122. The first RAL material 124 may, for example, be formed of and include one or more of ruthenium (Ru), zirconium (Zr), titanium (Ti), and a carbon-based material (e.g., amorphous carbon). The first RAL material 124 may be formed to have a desirable vertical height (e.g., in the Z-direction), such as a vertical height within a range of from about 5 nm to about 10 nm, from about 5 nm to about 7 nm, or about 5 nm.

The first EUV resist material 126 may be formed of and include at least one photoresist material formulated for EUV lithography (e.g., lithography utilizing EUV radiation having a wavelength of around 13.5 nm). The first EUV resist material 126 may, for example, be formed of and include one or more of a chemically amplified (CA) photoresist including a polymer matrix and a photoacid generator (PAG); a non-chemically amplified (NCA) photoresist substantially free of any PAGs; a hybrid photoresist including a combination of CA and NCA photoresist materials; and an inorganic photoresist including metal oxides or other inorganic materials. The first EUV resist material 126 may be formed to have a desirable vertical height (e.g., in the Z-direction), such as a vertical height within a range of from about 5 nm to about 10 nm, from about 5 nm to about 7 nm, or about 5 nm.

With continued reference to FIG. 2A, the initial digit line contact openings 128 may be formed to individually vertically extend completely through the first EUV resist material 126, the first RAL material 124, the first DARC material 122, the first UL material 120, the third dielectric material 116, the second dielectric material 114, and the first dielectric material 112; and partially through the pillar structures 104 of the base semiconductor structure 102. An individual initial digit line contact opening 128 may expose (e.g., uncover) the digit line contact region 104A of an individual pillar structure 104 of the base semiconductor structure 102. A lower boundary (e.g., floor, bottom) of an individual initial digit line contact openings 128 may vertically underlie uppermost surfaces of the base semiconductor structure 102 and insulative line structures 110 (and, hence, a lowermost boundary of the first dielectric material 112). For an individual pillar structure 104 of the base semiconductor structure 102, after forming the initial digit line contact openings 128, the digit line contact region 104A of the pillar structure 104 may be vertically recessed relative to the storage node contact regions 104B of the pillar structure 104. An upper boundary (e.g., top) of the digit line contact region 104A of the pillar structure 104 may vertically underlie the upper boundaries (e.g., tops) of the storage node contact regions 104B of the pillar structure 104.

Referring collectively to FIGS. 2A and 2B, the initial digit line contact openings 128 may be substantially horizontally centered about the digit line contact regions 104A of the pillar structures 104. As shown in FIG. 2B, an individual initial digit line contact opening 128 may be horizontally interposed between two (2) of the word line structures 108 (and, hence, two (2) of the additional filled trenches 107 (FIG. 2A)) neighboring one another in the Y-direction; may be horizontally interposed between two (2) of the filled trenches 106 neighboring one another in the X-direction; and may be horizontally interposed between two (2) of the storage node contact regions 104B of an individual pillar structure 104 in an additional horizontal direction angled relative to the Y-direction and the X-direction. In addition, a pitch P₁ (FIG. 2B) between initial digit line contact openings 128 neighboring one another in the Y-direction may be greater than an additional pitch P₂ (FIG. 2B) between word line structures 108 neighboring one another in the Y-direction. In some embodiments, the pitch P₁ between initial digit line contact openings 128 is greater than or equal to (e.g., substantially equal to) about 1.5 times (1.5×) the additional pitch P₂ between the word line structures 108. In some embodiments, the pitch P₁ between initial digit line contact openings 128 neighboring one another in the Y-direction is within a range of from about 20 nm to about 40 nm, such as from about 24 nm to about 36 nm.

The initial digit line contact openings 128 may individually be formed to have a desirable geometric configuration (e.g., dimensions, such as horizontal dimensions and vertical dimension(s); shape, such as horizontal cross-sectional shape(s) and vertical cross-sectional shape(s)). The geometric configuration of an individual initial digit line contact opening 128 may at least partially depend on the geometric configurations and spacing of other features (e.g., the pillar structures 104, the filled trenches 106, the word line structures 108) of the microelectronic device structure 100 that neighbor the initial digit line contact opening 128. In some embodiments, the initial digit line contact openings 128 are formed to individually exhibit a substantially cylindrical shape. A horizontal width (e.g., horizontal dimeter) of an individual initial digit line contact openings 128 may, for example, be within a range of from about 9 nm to about 30 (e.g., from about 9 nm to about 20 nm). In addition, the initial digit line contact openings 128 may individually vertically terminate at a desirable depth from an uppermost boundary (e.g., an uppermost surface) of the base semiconductor structure 102, such as a vertical depth within a range of from about 30 nm to about 50 nm (e.g., from about 35 nm to about 45 nm, or about 40 nm) from the uppermost boundary of the base semiconductor structure 102. The initial digit line contact openings 128 may individually vertically terminate (e.g., in the Z-direction) above uppermost boundaries of the word line structures 108, such as between uppermost boundaries and lowermost boundaries of the insulative line structures 110. Each of the initial digit line contact openings 128 may be formed to exhibit substantially the geometric configuration (e.g., substantially the same dimensions, and substantially same shape) as each other of the initial digit line contact openings 128, or at least one of the initial digit line contact openings 128 may be formed to exhibit a different geometric configuration (e.g., different dimension(s) and/or a different shape) than at least one other of the initial digit line contact openings 128.

The initial digit line contact openings 128 may be formed using a material removal process employing EUV lithography. A desirable pattern for the initial digit line contact openings 128 may be formed in the first EUV resist material 126 using EUV lithography, and then the resulting pattern in the first EUV resist material 126 may be transferred into a remainder of the first hardmask structure 118 and the pillar structures 104 using an etching (e.g., ion beam etching) process to form the initial digit line contact openings 128. In some embodiments, patterning of the first EUV resist material 126 using EUV lithography includes a single exposure to EUV radiation (e.g., a single EUV print) to form a pattern for the initial digit line contact openings 128. The single exposure to EUV radiation may, for example, form a pattern of features (e.g., photoexposed regions) in the first EUV resist material 126 with feature pitch corresponding to the pitch P₁ (e.g., within a range of from about 20 nm to about 40 nm, such as from about 24 nm to about 36 nm). In some embodiments, a critical dimension of an individual feature in the first EUV resist material 126 following exposure to the EUV radiation is within a range of from about 15 nm to about 20 nm, such as about 18 nm. Following the subsequent etching (e.g., ion beam etching) process, a critical dimension of an individual initial digit line contact opening 128 may be relatively smaller than the critical dimension of an individual feature in the first EUV resist material 126. In some embodiments, the critical dimension of an individual initial digit line contact opening 128 is at least about two (2) nm smaller than (e.g., within a range of from about 2 nm to about 8 nm, from about 3 nm to about 7 nm, from about 4 nm to about 6 nm, or about 5 nm) the associated feature (e.g., photoexposed region) initially formed in the first EUV resist material 126 by way of EUV lithography.

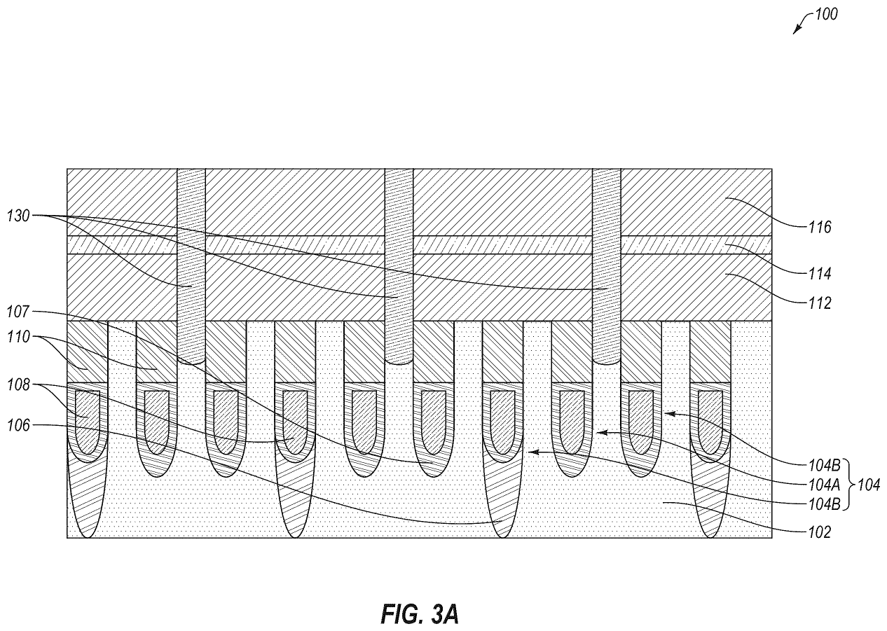

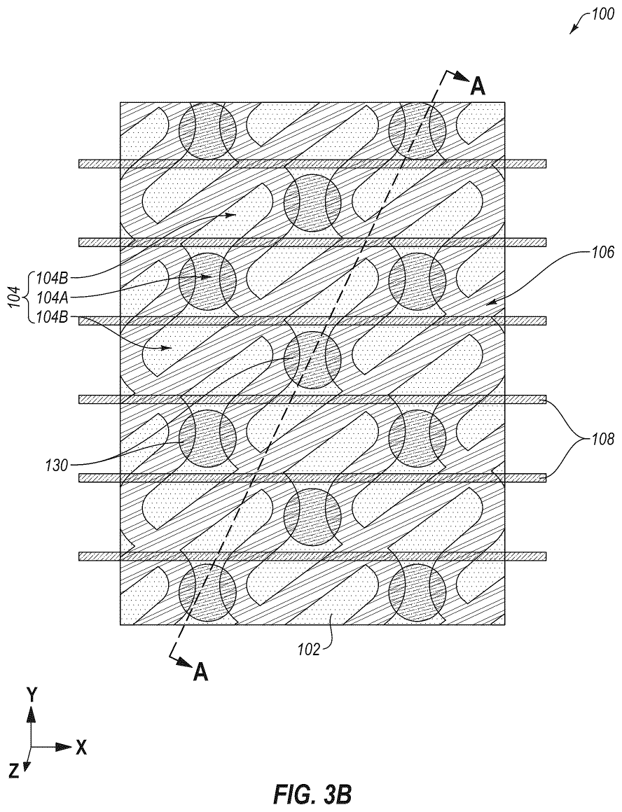

Referring next to FIG. 3A, first sacrificial structures 130 may be formed within the initial digit line contact openings 128 (FIGS. 2A and 2B), and the first hardmask structure 118 (FIG. 2A) may be removed. Following the removal of the first hardmask structure 118 (FIG. 2A), uppermost boundaries (e.g., uppermost surfaces) of the first sacrificial structures 130 may be substantially coplanar with an uppermost boundary (e.g., an uppermost surface) of the third dielectric material 116. FIG. 3B is a top-down view of the microelectronic device structure 100 at the processing stage shown in FIG. 3A, wherein the line A-A corresponds to the longitudinal cross-section of the microelectronic device structure 100 depicted in FIG. 3A. For clarity in understanding the drawings and related description, some features (e.g., structures, materials, regions) of the microelectronic device structure 100 at the processing stage of FIGS. 3A and 3B that are depicted in FIG. 3A are not depicted in FIG. 3B, and vice versa. However, it will be understood that any feature depicted in at least one of FIGS. 3A and 3B may be included in the microelectronic device structure 100 at the processing stage of FIGS. 3A and 3B.

The first sacrificial structures 130 may be formed of and include a sacrificial material that is selectively etchable relative at least to the pillar structures 104, insulative line structures 110, the first dielectric material 112, the second dielectric material 114, and the third dielectric material 116. In some embodiments, the first sacrificial structures 130 are formed of and include a carbon-containing material (e.g., a carbon-based material), such as amorphous carbon.

To form the first sacrificial structures 130, sacrificial material (e.g., carbon-containing material) may be formed inside and outside of the initial digit line contact openings 128 (FIG. 2A), and then portions of the first hardmask structure 118 (FIG. 2A) and the sacrificial material may be removed (e.g., through a CMP process).

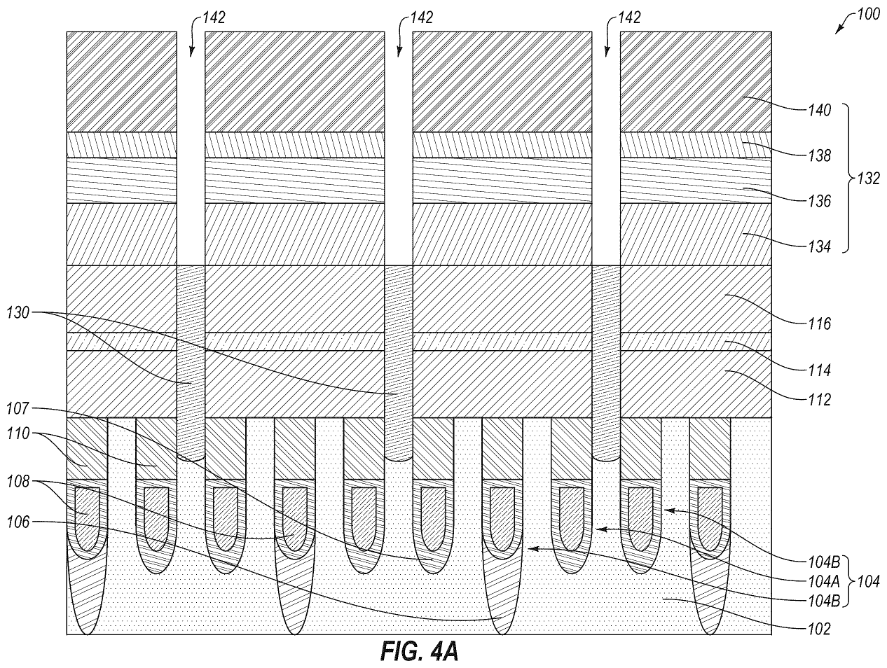

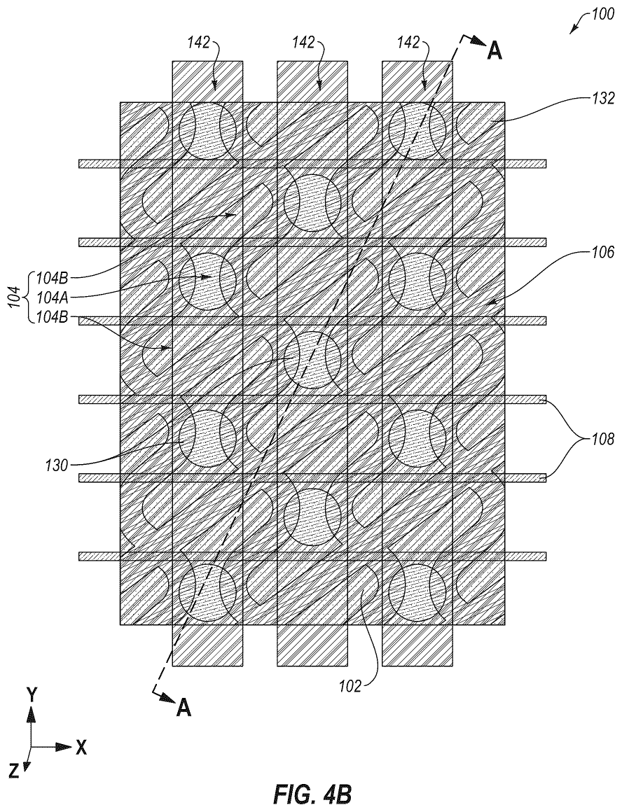

Referring next to FIG. 4A, a second hardmask structure 132 may be formed on or over the third dielectric material 116 and the first sacrificial structures 130, and linear mask openings 142 may be formed to vertically extend through the second hardmask structure 132 to expose (e.g., uncover) the first sacrificial structures 130 and portions of the third dielectric material 116. As described in further detail below, the linear mask openings 142 may individually be formed to horizontally overlap multiple of the first sacrificial structures 130. FIG. 4B is a top-down view of the microelectronic device structure 100 at the processing stage shown in FIG. 4A, wherein the line A-A corresponds to the longitudinal cross-section of the microelectronic device structure 100 depicted in FIG. 4A. For clarity in understanding the drawings and related description, some features (e.g., structures, materials, regions) of the microelectronic device structure 100 at the processing stage of FIGS. 4A and 4B that are depicted in FIG. 4A are not depicted in FIG. 4B, and vice versa. However, it will be understood that any feature depicted in at least one of FIGS. 4A and 4B may be included in the microelectronic device structure 100 at the processing stage of FIGS. 4A and 4B.

The second hardmask structure 132 may be formed to comprise an additional multi-layered lithography stack. For example, as shown in FIG. 4A, the second hardmask structure 132 may be formed to include a second UL material 134 on or over the third dielectric material 116, a second DARC material 136 on or over the second UL material 134, a second RAL material 138 on or over the second DARC material 136, and a second EUV resist material 140 on or over the second RAL material 138. The foregoing features of the second hardmask structure 132 are described in further detail below.

The second UL material 134 of the second hardmask structure 132 may be formed of and include at least one material having desirable adhesion and planarization characteristics. A material composition of the second UL material 134 may be selected, at least in part, based on material compositions of the third dielectric material 116 and the second DARC material 136. The material composition of the second UL material 134 may be substantially the same as or may be different than the material composition of the first UL material 120 (FIG. 2A) of the first hardmask structure 118 (FIG. 2A). In some embodiments, the second UL material 134 is formed of and includes a carbon-containing material (e.g., amorphous carbon). The second UL material 134 may be formed to have a desirable vertical height (e.g., in the Z-direction), such as a vertical height within a range of from about 20 nm to about 50 nm, from about 25 nm to about 35 nm, or about 30 nm.

The second DARC material 136 may be formed of and include at least one material formulated to reduce reflections and improve pattern transfer during lithography processes. A material composition of the second DARC material 136 may be substantially the same as or may be different than the material composition of the first DARC material 122 (FIG. 2A) of the first hardmask structure 118 (FIG. 2A). In some embodiments, the second DARC material 136 is formed of and includes an Si-rich DARC material including a relatively high concentration of silicon. The second DARC material 136 may be formed to have a desirable vertical height (e.g., in the Z-direction), such as a vertical height within a range of from about 10 nm to about 25 nm, from about 10 nm to about 15 nm, or about 10 nm.

The second RAL material 138 may be formed of and include at least one material formulated to enhance adhesion of the first EUV resist material 126 to the second DARC material 136. A material composition of the second RAL material 138 may be selected, at least in part, based on material compositions of the second EUV resist material 140 and the second DARC material 136. The material composition of the second RAL material 138 may be substantially the same as or may be different than the material composition of the first RAL material 124 (FIG. 2A) of the first hardmask structure 118 (FIG. 2A). The second RAL material 138 may be formed to have a desirable vertical height (e.g., in the Z-direction), such as a vertical height within a range of from about 5 nm to about 10 nm, from about 5 nm to about 7 nm, or about 5 nm.

The second EUV resist material 140 may be formed of and include at least one photoresist material formulated for EUV lithography (e.g., lithography utilizing EUV radiation having a wavelength of around 13.5 nm). A material composition of the second EUV resist material 140 may be substantially the same as or may be different than the material composition of the first EUV resist material 126 (FIG. 2A) of the first hardmask structure 118 (FIG. 2A). The second EUV resist material 140 may be formed to have a desirable vertical height (e.g., in the Z-direction), such as a vertical height within a range of from about 10 nm to about 60 nm, from about 20 nm to about 50 nm, or about 40 nm.

Referring collectively to FIGS. 4A and 4B, the linear mask openings 142 may individually be formed to vertically extend completely through the second hardmask structure 132 to upper boundaries (e.g., upper surfaces) of multiple first sacrificial structures 130 and portions of the third dielectric material 116. As shown in FIG. 4B, the linear mask openings 142 may horizontally extend in parallel with one another in the Y-direction, and may be separated from one another in the X-direction by remaining portions of the second hardmask structure 132. As described in further detail below, the formation of the linear mask openings 142 may facilitate the subsequent formation of conductive contact structures (e.g., digit line contact structures) and conductive line structures (e.g., digit line structures) for the microelectronic device structure 100 by way of a damascene process.

A vertical height (e.g., in the Z-direction) of each of the linear mask openings 142 may correspond to (e.g., be substantially the same as) a vertical height of the second hardmask structure 132. By way of non-limiting example, an individual linear mask opening 142 may have a vertical height be within a range from about 45 nm to about 150 nm, such as from about 50 nm to about 140 nm.

Referring to FIG. 4B, horizontal widths and positions in the X-direction of the linear mask openings 142 may at least partially depend on horizontal widths and positions in the X-direction of the first sacrificial structures 130 (and, hence, of the digit line contact regions 104A of the pillar structures 104 of the base semiconductor structure 102). Each of the linear mask openings 142 may have a horizontal width and a horizontal position permitting a horizontal center, in the X-direction, of the linear mask opening 142 to be substantially horizontally aligned with a horizontal center, in the X-direction, of one or more (e.g., a column of) of the first sacrificial structures 130. A ratio of the horizontal width, in the X-direction, of an individual linear mask opening 142 to the horizontal width, in the X-direction, of an individual first sacrificial structure 130 may be within range of from about 0.5:1 to about 3.0:1, such as from about 1:1 to about 2:1, about 1:1. Each of the linear mask openings 142 may, for example, be formed to have a horizontal width, in the X-direction, within a range of from about 5 nm to about 15, such as from about 7 nm to about 15 nm, from about 7 nm to about 12 nm, or from about 7 nm to about 10 nm. In addition, a pitch between two linear mask openings 142 horizontally neighboring one another in the X-direction may be within a range of from about 20 nm to about 40 nm, such as from about 20 nm to about 35 nm, or from about 25 nm to about 35 nm.

The linear mask openings 142 may be formed using a material removal process employing EUV lithography. A desirable pattern for the linear mask openings 142 may be formed in the second EUV resist material 140 using EUV lithography, and then the resulting pattern in the second EUV resist material 140 may be transferred into a remainder of the second hardmask structure 132 (including the second RAL material 138, the second DARC material 136, and the second UL material 134 thereof) using an etching (e.g., ion beam etching) process to form the linear mask openings 142. In some embodiments, patterning of the second EUV resist material 140 using EUV lithography includes a single exposure to EUV radiation (e.g., a single EUV print) to form a pattern for the linear mask openings 142. The single exposure to EUV radiation may, for example, form a pattern of features (e.g., photoexposed regions) in the second EUV resist material 140 with feature pitch within a range of from about 20 nm to about 40 nm, such as from about 24 nm to about 36 nm. In some embodiments, a critical dimension of an individual feature in the second EUV resist material 140 following exposure to the EUV radiation is within a range of from about 15 nm to about 20 nm, such as about 18 nm. Following the subsequent etching (e.g., ion beam etching) process, a critical dimension of an individual linear mask openings 142 may be relatively smaller than the critical dimension of an individual feature in the second EUV resist material 140. In some embodiments, the critical dimension of an individual linear mask opening 142 is a least about 5 nm smaller than the associated feature (e.g., photoexposed region) initially formed in the second EUV resist material 140 by way of EUV lithography.

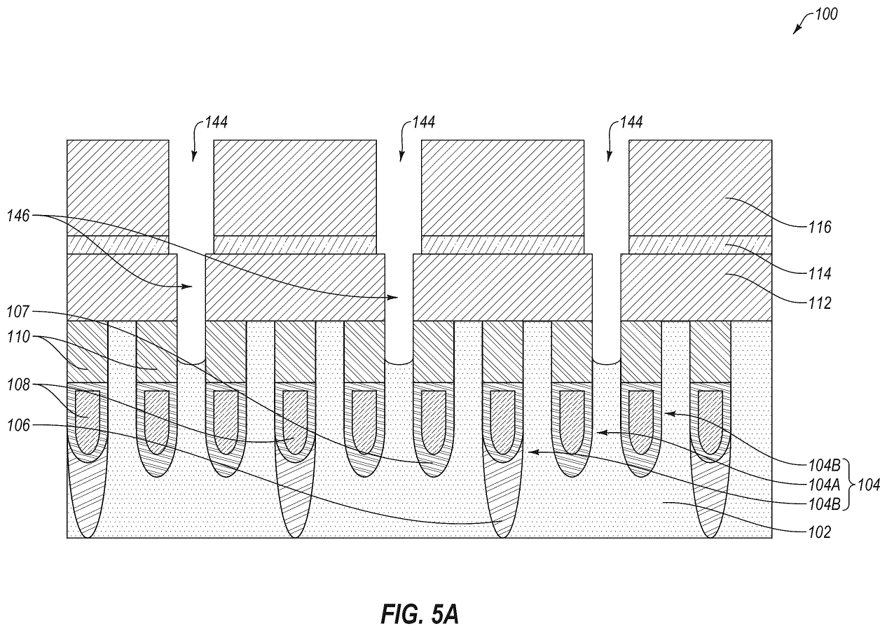

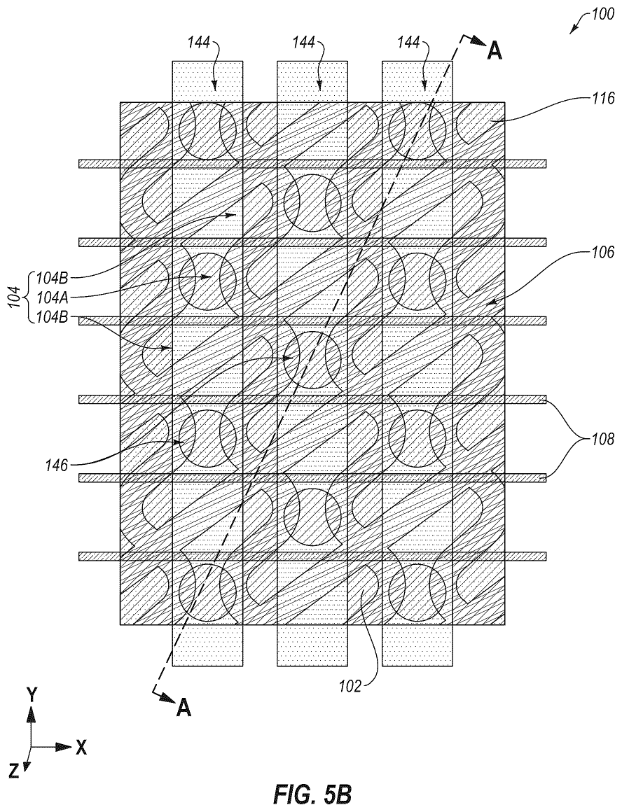

Referring next to FIG. 5A, a pattern of the linear mask openings 142 (FIGS. 4A and 4B) may be extended into the third dielectric material 116 and upper portions of the first sacrificial structures 130 (FIGS. 4A and 4B) to form digit line trenches 144 (e.g., bit line trenches, data line trenches); remaining portions of the second hardmask structure 132 (FIGS. 4A and 4B) may be removed; and remaining portions (e.g., lower portions) of the first sacrificial structures 130 may be removed to from digit line contact openings 146 (e.g., bit line contact openings, data line contact openings) integral and continuous with the digit line trenches 144. The digit line trenches 144 may vertically terminate at or within vertical boundaries of the second dielectric material 114. The digit line contact openings 146 may vertically extend from the digit line trenches 144 to upper boundaries (e.g., upper surfaces) of the pillar structures 104 within horizontal areas of the digit line contact regions 104A thereof. The digit line trenches 144 and the first contact openings 146 may, in combination, expose the digit line contact regions 104A of the pillar structures 104, as described in further detail below. FIG. 5B is a top-down view of the microelectronic device structure 100 at the processing stage shown in FIG. 5A, wherein the line A-A corresponds to the longitudinal cross-section of the microelectronic device structure 100 depicted in FIG. 5A. For clarity in understanding the drawings and related description, some features (e.g., structures, materials, regions) of the microelectronic device structure 100 at the processing stage of FIGS. 5A and 5B that are depicted in FIG. 5A are not depicted in FIG. 5B, and vice versa. However, it will be understood that any feature depicted in at least one of FIGS. 5A and 5B may be included in the microelectronic device structure 100 at the processing stage of FIGS. 5A and 5B.

Referring collectively to FIGS. 5A and 5B, the digit line trenches 144 may individually be formed to vertically extend completely through the third dielectric material 116 (FIG. 5A) and to or into the second dielectric material 114 (FIG. 5A). Horizontal dimensions and a pattern of the digit line trenches 144 may respectively correspond to (e.g., may be substantially the same as) the horizontal dimensions and the pattern of the linear mask openings 142 (FIGS. 4A and 4B) formed in the second hardmask structure 132 (FIGS. 4A and 4B) at the processing stage of FIGS. 4A and 4B. As shown in FIG. 5B, the digit line trenches 144 may horizontally extend in parallel with one another in the Y-direction.

Following the formation of the digit line trenches 144, remaining portions of the second hardmask structure 132 (FIGS. 4A and 4B) and the first sacrificial structures 130 (FIGS. 4A and 4B) may be removed (e.g., through a stripping and cleaning process). The removal of the remaining portions of the first sacrificial structures 130 forms the digit line contact openings 146. Horizontal dimensions and a pattern of the digit line contact openings 146 may respectively correspond to (e.g., may be substantially the same as) the horizontal dimensions and the pattern of the first sacrificial structures 130 (FIGS. 4A and 4B).

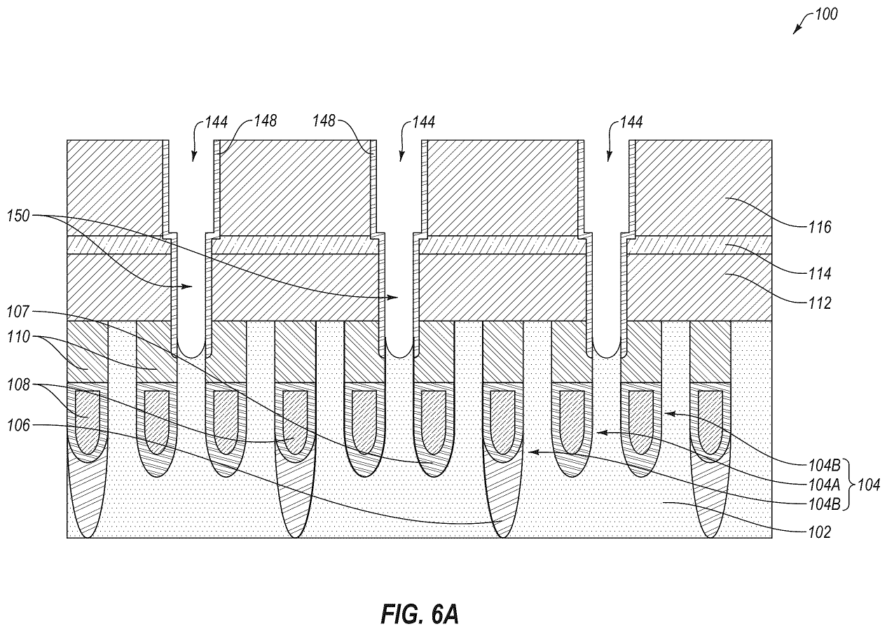

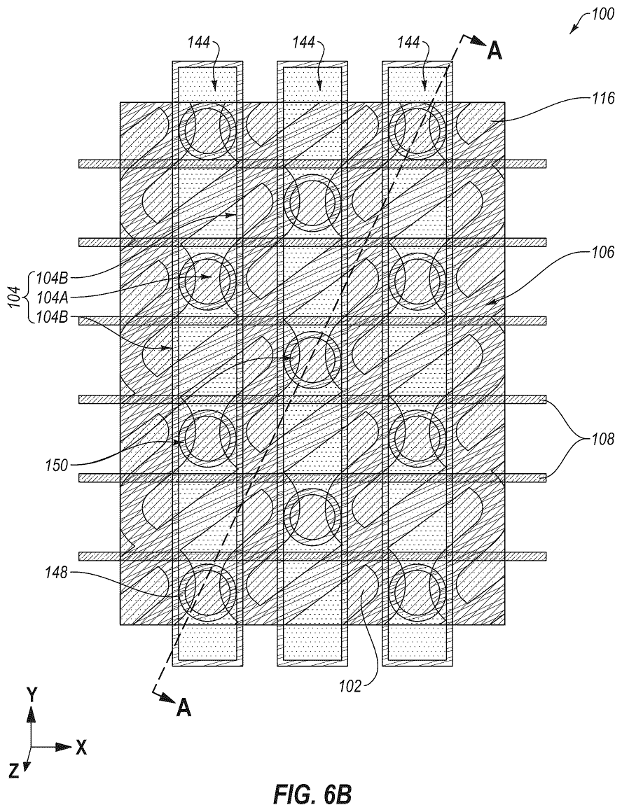

Referring next to FIG. 6A, a first spacer material 148 may be formed (e.g., substantially conformally formed) to extend continuously on or over surfaces of the microelectronic device structure 100 defining the digit line trenches 144 and the digit line contact openings 146, and then portions of at least the first spacer material 148 at bottoms of the digit line contact openings 146 (FIGS. 5A and 5B) may be removed (e.g., by way of so-called “punch through” etching) to expose the digit line contact regions 104A of the pillar structures 104. As shown in FIG. 6A, the material removal process may also remove upper portions of the digit line contact regions 104A of the pillar structures 104, to form extended digit line contact openings 150 from the digit line contact openings 146 (FIGS. 5A and 5B). FIG. 6B is a top-down view of the microelectronic device structure 100 at the processing stage shown in FIG. 6A, wherein the line A-A corresponds to the longitudinal cross-section of the microelectronic device structure 100 depicted in FIG. 6A. For clarity in understanding the drawings and related description, some features (e.g., structures, materials, regions) of the microelectronic device structure 100 at the processing stage of FIGS. 6A and 6B that are depicted in FIG. 6A are not depicted in FIG. 6B, and vice versa. However, it will be understood that any feature depicted in at least one of FIGS. 6A and 6B may be included in the microelectronic device structure 100 at the processing stage of FIGS. 6A and 6B.

As shown in FIG. 6A, the first spacer material 148 partially (e.g., less than completely) fills the digit line contact openings 146 (FIGS. 5A and 5B) and the digit line trenches 144. The first spacer material 148 may substantially completely cover surfaces of the microelectronic device structure 100 defining the digit line trenches 144 and the digit line contact openings 146. The first spacer material 148 may serve as an isolation material for conductive structures (e.g., digit line structures, digit line contact structures) subsequently formed in remaining (e.g., unfilled) portions of the digit line trenches 144 and the digit line contact openings 146, as described in further detail below.

The first spacer material 148 may be formed of and include dielectric material. In some embodiments, the first spacer material 148 is formed of and includes a dielectric nitride material (e.g., SiN_{y}, such as Si₃N₄). In additional embodiments, the first spacer material 148 is formed of and includes at least one low-K (low-dielectric constant) dielectric material, such as one or more of silicon oxycarbide (SiOₓC_{y}), silicon oxynitride (SiOₓN_{y}), hydrogenated silicon oxycarbide (SiCₓO_{y}H_{z}), and silicon oxycarbonitride (SiOₓC_{z}N_{y}). In addition, the first spacer material 148 may be formed to have a thickness within a range of from about 1 nm to about 5 nm, such as from about 2 nm to about 4 nm, or from about 2 nm to about 3 nm.

Following the formation of the first spacer material 148, portions thereof at lower boundaries (e.g., bottoms) of the digit line contact openings 146 (FIGS. 5A and 5B) may be removed, while at least partially (e.g., substantially) maintaining additional portions thereof at side boundaries (e.g., sides) of the digit line contact openings 146 (FIGS. 5A and 5B). In some embodiments, the removal process also partially removes portions of the pillar structures 104 within horizontal areas of the digit line contact regions 104A. As shown in FIG. 6A, lowermost boundaries of the resulting extended digit line contact openings 150 may vertically overlie uppermost boundaries of the word line structures 108. For example, the lowermost boundaries of the extended digit line contact openings 150 may be positioned within vertical boundaries (e.g., between uppermost boundaries and lowermost boundaries) of the insulative line structures 110. In some embodiments, the lowermost boundaries of the extended digit line contact openings 150 are vertically offset from (e.g., vertically overlie) the uppermost boundaries of the word line structures 108 by greater than or equal to about 10 nm.

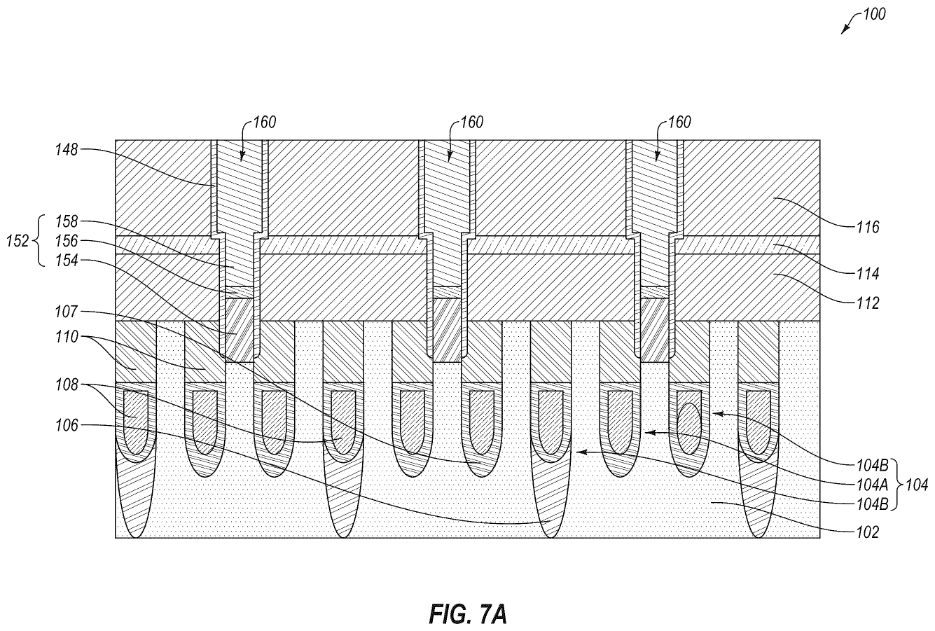

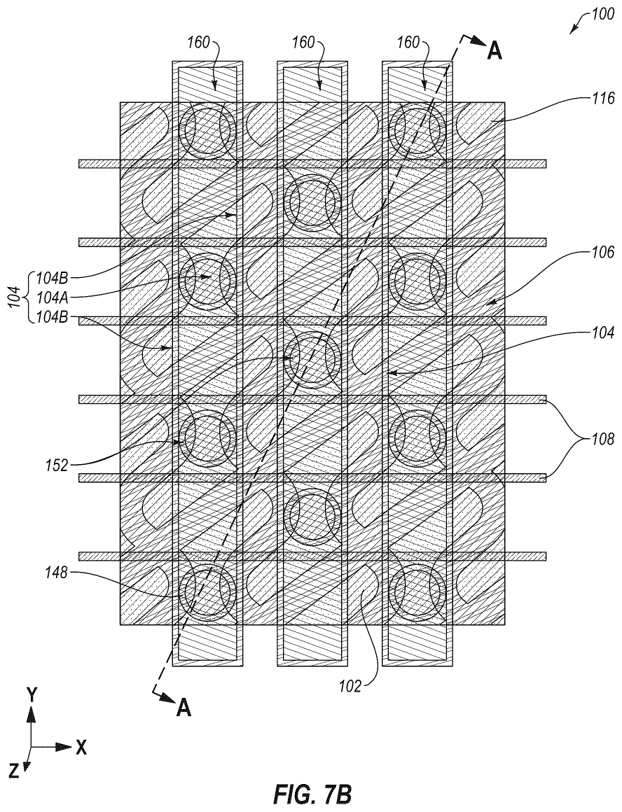

Referring next to FIG. 7A, digit line contact structures 152 (e.g., bit line contact structures, data line contact structures) may be formed within the extended digit line contact openings 150 (FIGS. 6A and 6B), and digit line structures 160 (e.g., bit line structures, data line structures) may be formed over the digit line contact structures 152 and within the digit line trenches 144 (FIGS. 6A and 6B). An individual digit line structure 160 may be integral and continuous (e.g., unitary) with multiple (e.g., a column of) digit line contact structures 152. FIG. 7B is a top-down view of the microelectronic device structure 100 at the processing stage shown in FIG. 7A, wherein the line A-A corresponds to the longitudinal cross-section of the microelectronic device structure 100 depicted in FIG. 7A. For clarity in understanding the drawings and related description, some features (e.g., structures, materials, regions) of the microelectronic device structure 100 at the processing stage of FIGS. 7A and 7B that are depicted in FIG. 7A are not depicted in FIG. 7B, and vice versa. However, it will be understood that any feature depicted in at least one of FIGS. 7A and 7B may be included in the microelectronic device structure 100 at the processing stage of FIGS. 7A and 7B.

Referring to FIG. 7A, the digit line contact structures 152 may individually be formed to include a first portion 154 (e.g., a lower portion) vertically overlying the digit line contact region 104A of an individual pillar structure 104; a second portion 156 (e.g., a middle portion) vertically overlying the first portion 154; and a third portion 158 (e.g., an upper portion) vertically overlying the second portion 156. The first portion 154 may directly physically contact the digit line contact region 104A of the pillar structure 104, the third portion 158 may directly physically contact an individual digit line structure 160, and the second portion 156 may vertically extend from and between the first portion 154 and the third portion 158. A geometric configuration (e.g., shape, dimensions) of an individual digit line contact structure 152 may substantially correspond to (e.g., may be substantially the same as) a geometric configuration of the remainder (e.g., remaining portion following the formation of the first spacer material 148) of the extended digit line contact opening 150 (FIGS. 6A and 6B) within which the digit line contact structure 152 is formed.

The first portion 154 of an individual digit line contact structure 152 may be formed of and include epitaxial semiconductor material, such as epitaxial polycrystalline silicon. The first portion 154 of the digit line contact structure 152 may be epitaxially grown from semiconductor material of the digit line contact region 104A of the pillar structure 104 in contact therewith. For an individual digit line contact structure 152, an upper boundary of the first portion 154 thereof may be vertically positioned below, at, or above the uppermost boundaries of the insulative line structures 110. In some embodiments, upper boundaries of the first portions 154 of the digit line contact structures 152 are vertically positioned at or above the uppermost boundaries of the insulative line structures 110.

The second portion 156 of an individual digit line contact structure 152 may be formed of and include metal silicide material, such as one or more of cobalt silicide (CoSiₓ), tungsten silicide (WSiₓ), tantalum silicide (TaSiₓ), molybdenum silicide (MoSiₓ), nickel silicide (NiSiₓ), and titanium silicide (TiSiₓ). For an individual digit line contact structure 152, an upper boundary of the second portion 156 thereof may be vertically positioned below a lowermost boundary of the second dielectric material 114, such as between the lowermost boundary of the second dielectric material 114 and the uppermost boundaries of the insulative line structures 110.

The third portion 158 of an individual digit line contact structure 152 may be formed of and include conductive material, such as one or more of at least one elemental metal (e.g., W, Ti, Mo, Nb, V, Hf, Ta, Cr, Zr, Fe, Ru, Os, Co, Rh, Ir, Ni, Pd, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), and a conductive metal-containing material (e.g., a conductive metal nitride, a conductive metal carbide, a conductive metal oxide). In some embodiments, the third portion 158 is formed of and includes elemental metal, such as one or more of Ru, Mo, Ti, and W. For an individual digit line contact structure 152, an upper boundary of the third portion 158 thereof may be vertically positioned above the lowermost boundary of the second dielectric material 114 and below, at, or above an uppermost boundary of the second dielectric material 114.

Still referring to FIG. 7A, the digit line structures 160 may substantially fill portions of the digit line trenches 144 (FIGS. 6A and 6B) remaining unfilled following formation of the first spacer material 148. A geometric configuration (e.g., shape, dimensions) of an individual digit line structure 160 may substantially correspond to (e.g., may be substantially the same as) a geometric configuration of the remainder (e.g., remaining portion following the formation of the first spacer material 148) of the digit line trenches 144 (FIGS. 6A and 6B) within which the digit line structures 160 is formed. As shown in FIG. 7B, the digit line structures 160 may exhibit horizontally elongate shapes, and may horizontally extend in parallel with one another in the Y-direction (and, hence, orthogonal to the word line structures 108 horizontally extending in parallel with one another in the X-direction).

The digit line structures 160 may individually be formed of and include conductive material, such as one or more of at least one elemental metal (e.g., W, Ti, Mo, Nb, V, Hf, Ta, Cr, Zr, Fe, Ru, Os, Co, Rh, Ir, Ni, Pd, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), and a conductive metal-containing material (e.g., a conductive metal nitride, a conductive metal carbide, a conductive metal oxide). A material composition of the digit line structures 160 may be substantially the same as a material composition of the third portions 158 of the digit line contact structures 152. In some embodiments, the digit line structures 160 are individually formed of and include elemental metal, such as one or more of Ru, Mo, Ti, and W. As shown in FIG. 7A, for an individual digit line structure 160, an upper boundary thereof may be formed to be substantially coplanar with an uppermost boundary of the third dielectric material 116.

To form the digit line contact structures 152 and the digit line structures 160, epitaxial semiconductor material (e.g., epitaxial polycrystalline silicon) may be epitaxially grown within the extended digit line contact openings 150 (FIGS. 6A and 6B) and then etched back to form the first portions 154 of the digit line contact structures 152. Thereafter conductive material may be formed inside and outside of remainders of the extended digit line contact openings 150 (FIGS. 6A and 6B) and the digit line trenches 144 (FIGS. 6A and 6B), and subjected to thermal processing (e.g., rapid thermal processing (RTP)) to form the second portions 156 of the digit line contact structures 152. A wet cleaning process may then be performed, followed by the formation of additional conductive material inside and outside of new remainders of the extended digit line contact openings 150 (FIGS. 6A and 6B) and the digit line trenches 144 (FIGS. 6A and 6B) to form the third portions 158 of the digit line contact structures 152. Thereafter portions of the conductive material (if any) and the additional conductive material overlying an uppermost boundary (e.g., an uppermost surface) of the third dielectric material 116 may be removed (e.g., by way of a CMP process) to expose the third dielectric material 116 and form the digit line structures 160.

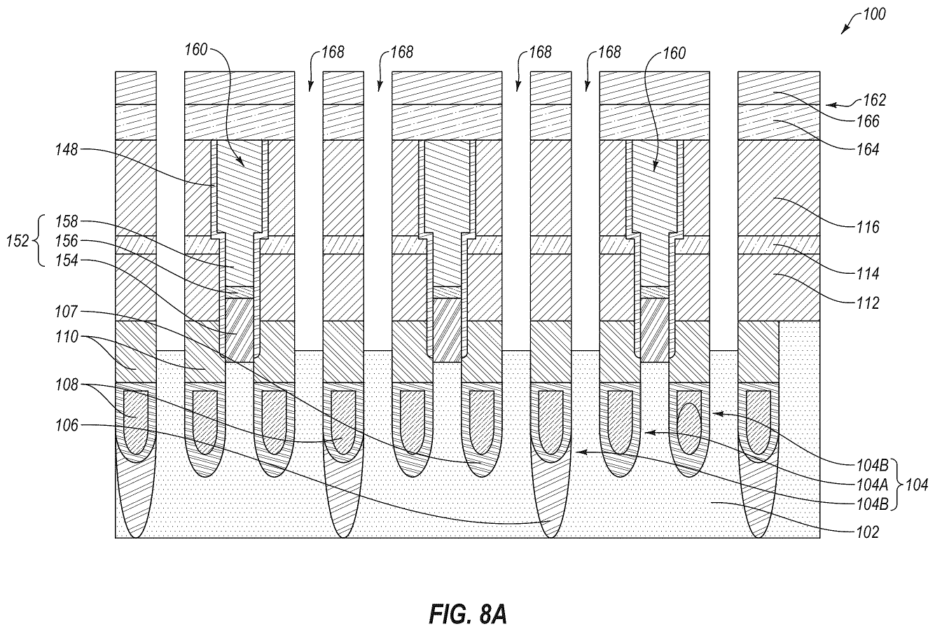

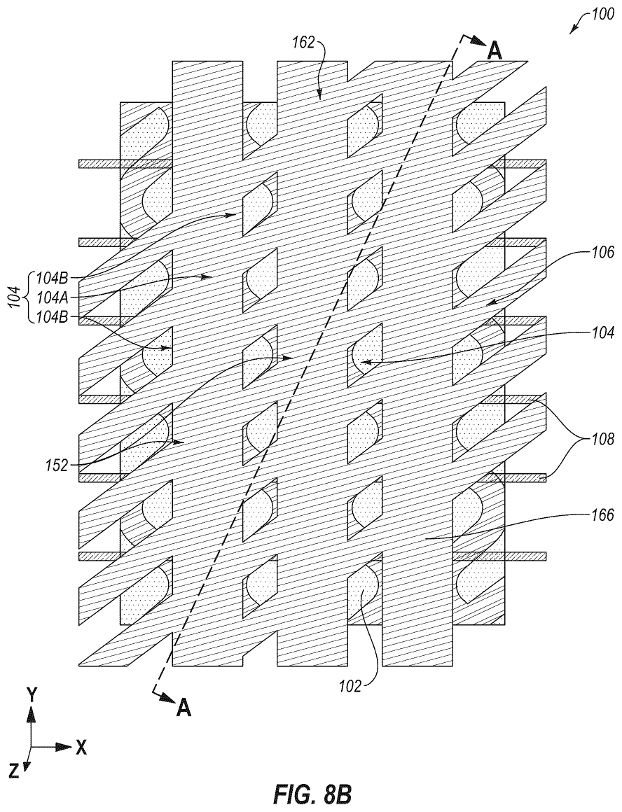

Referring next to FIG. 8A, an additional mask structure 162 (e.g., an additional hardmask structure) may be formed on or over the third dielectric material 116 and the digit line structures 160; and storage node contact openings 168 (e.g., cell contact openings) may be formed to vertically extend through the additional mask structure 162, the third dielectric material 116, the second dielectric material 114, and the first dielectric material 112 and into the pillar structures 104 of the base semiconductor structure 102. As described in further detail below, the storage node contact openings 168 may be formed to horizontally overlap the storage node contact regions 104B of the pillar structures 104. FIG. 8B is a top-down view of the microelectronic device structure 100 at the processing stage shown in FIG. 8A, wherein the line A-A corresponds to the longitudinal cross-section of the microelectronic device structure 100 depicted in FIG. 8A. For clarity in understanding the drawings and related description, some features (e.g., structures, materials, regions) of the microelectronic device structure 100 at the processing stage of FIGS. 8A and 8B that are depicted in FIG. 8A are not depicted in FIG. 8B, and vice versa. However, it will be understood that any feature depicted in at least one of FIGS. 8A and 8B may be included in the microelectronic device structure 100 at the processing stage of FIGS. 8A and 8B.

Referring to FIG. 8A, the additional mask structure 162 may be formed to include a fourth dielectric material 164 on or over the digit line structures 160 and the third dielectric material 116; and a fifth dielectric material 166 on or over the fourth dielectric material 164. The fourth dielectric material 164 and the fifth dielectric material 166 of the additional mask structure 162 may together form a second dielectric stack (e.g., a second stack of dielectric materials, a second dielectric stack structure). As described in further detail below, first portions of the additional mask structure 162, including first portions of the fourth dielectric material 164 and the fifth dielectric material 166 thereof, may substantially horizontally extend over and cover the digit line structures 160; and second portions of the additional mask structure 162, including second portions of the fourth dielectric material 164 and the fifth dielectric material 166 thereof, may horizontally extend over and cover portions of the third dielectric material 116 within horizontal areas of the filled trenches 106.

The fourth dielectric material 164 may be formed of and include at least one dielectric material that substantially mitigates oxidation of the digit line structures 160. For example, the fourth dielectric material 164 may be formed of includes at least one dielectric nitride material (e.g., SiN_{y}, such as Si₃N₄). In some embodiments, the fourth dielectric material 164 is formed of and includes dielectric nitride material formed at relatively lower temperatures (e.g., temperatures less than or equal to about 400° C., such as less than or equal to about 350° C.) than those employed to form the fifth dielectric material 166. The fourth dielectric material 164 may be formed to have a desirable vertical height (e.g., in the Z-direction), such as a vertical height within a range of from about 5 nm to about 15 nm, from about 7 nm to about 12 nm, or about 10 nm.

The fifth dielectric material 166 may be formed to substantially cover an uppermost surface of the fourth dielectric material 164. A material composition of the fifth dielectric material 166 may be substantially the same as or may be different than a material composition of the fourth dielectric material 164. For example, the fifth dielectric material 166 may be formed of includes at least one dielectric nitride material (e.g., SiN_{y}, such as Si₃N₄). In some embodiments, the fifth dielectric material 166 is formed of and includes dielectric nitride material formed at relatively higher temperatures (e.g., temperatures greater than about 400° C., such as greater than or equal to about 600° C.) than those employed to form the fourth dielectric material 164. The fifth dielectric material 166 may be formed to have a desirable vertical height (e.g., in the Z-direction), such as a vertical height within a range of from about 15 nm to about 25 nm, from about 17 nm to about 22 nm, or about 20 nm.

Referring to FIG. 8B, the additional mask structure 162 may be patterned (e.g., through a single pitch patterning process; or through a multiple pitch patterning process, such as a double pitch patterning process) to include first portions individually extending substantially linearly in the Y-direction, and second portions extending substantially linearly an additional horizontal direction angled relative to each of the Y-direction and the X-direction. The first portions of the additional mask structure 162 may substantially cover and protect the digit line structures 160 (FIG. 8A), and may form first opposing horizontal boundaries (e.g., first opposing side boundaries) for individual storage node contact openings 168. The second portions of the additional mask structure 162 may horizontally intersect the first portions of the additional mask structure 162, and may form second opposing horizontal boundaries (e.g., second opposing side boundaries) for individual storage node contact openings 168. In some embodiments, horizontal centers, in the X-direction, of the first portions of the additional mask structure 162 are substantially aligned with horizontal centers, in the X-direction, of the digit line structures 160 (FIG. 8A); and horizontal centers, in the additional horizontal direction angled relative to the X-direction and the Y-direction, of the second portions of the additional mask structure 162 are substantially aligned with horizontal centers, in the additional horizontal direction, of some of the filled trenches 106 (FIG. 8A). The first portions and the second portions of the additional mask structure 162 may together establish the horizontal boundaries and horizontal positions of the storage node contact openings 168, to ensure the storage node contact openings 168 horizontally overlap the storage node contact regions 104B of the pillar structures 104 but do not horizontally overlap the digit line contact regions 104A of the pillar structures 104.

With returned reference to FIG. 8A, the storage node contact openings 168 may be formed to individually vertically extend completely through the fifth dielectric material 166, the fourth dielectric material 164, the third dielectric material 116, the second dielectric material 114, and the first dielectric material 112; and partially through the pillar structures 104 of the base semiconductor structure 102. An individual storage node contact opening 168 may expose (e.g., uncover) one of the storage node contact regions 104B of an individual pillar structure 104 of the base semiconductor structure 102. A lower boundary (e.g., floor, bottom) of an individual storage node contact opening 168 may vertically underlie uppermost surfaces of the insulative line structures 110 (and, hence, a lowermost boundary of the first dielectric material 112). For an individual pillar structure 104 of the base semiconductor structure 102, after forming the storage node contact openings 168, the storage node contact region 104B of the pillar structure 104 may each be vertically recessed relative to the insulative line structures 110. Upper boundaries (e.g., tops) of the storage node contact regions 104B of the pillar structure 104 may be vertically positioned below, at, or above the upper boundary (e.g., top) of the digit line contact region 104A of the pillar structure 104. In some embodiments, the upper boundaries of the storage node contact regions 104B of the pillar structure 104 (and, hence, the lower boundaries of the storage node contact openings 168) are vertically positioned at or above the upper boundary of the digit line contact region 104A of the pillar structure 104.

Referring collectively to FIGS. 8A and 8B, the storage node contact openings 168 horizontally overlap the storage node contact regions 104B of the pillar structures 104. As shown in FIG. 8B, an individual storage node contact opening 168 may be horizontally interposed between two (2) of the word line structures 108 (and, hence, two (2) of the additional filled trenches 107 (FIG. 8A)) neighboring one another in the Y-direction; may be horizontally interposed between two (2) of the filled trenches 106 neighboring one another in the X-direction; and may horizontally neighbor the digit line contact region 104A of an individual pillar structure 104 in an additional horizontal direction angled relative to the Y-direction and the X-direction.

The storage node contact openings 168 may individually be formed to have a desirable geometric configuration (e.g., dimensions, such as horizontal dimensions and vertical dimension(s); shape, such as horizontal cross-sectional shape(s) and vertical cross-sectional shape(s)). The geometric configuration of an individual storage node contact opening 168 may at least partially depend on the geometric configuration of the additional mask structure 162, as well as the geometric configurations and spacing of other features (e.g., the digit line structures 160, the digit line contact structures 152, the pillar structures 104, the filled trenches 106, the word line structures 108) of the microelectronic device structure 100 that neighbor the storage node contact opening 168. As shown in FIG. 8B, the storage node contact openings 168 may be formed to individually exhibit an elongate horizontal cross-sectional shape, such as an elongate, quadrilateral horizontal cross-sectional shape. In some embodiments, the storage node contact openings 168 are formed to individually exhibit a parallelogram horizontal cross-sectional shape. The parallelogram horizontal cross-sectional shape may include two sides having different horizontal dimensions than two other sides, or may include four sides all having substantially the same horizontal dimensions as one another. In addition, angles defined by corners of the parallelogram horizontal cross-sectional shape individually be greater than or less than 90 degrees (e.g., may not be right angles). The elongate horizontal cross-sectional shape may facilitate desirable exposure (e.g., substantial exposure) of the storage node contact regions 104B (FIG. 8A) of the pillar structures 104 (FIG. 8A). In addition, the storage node contact openings 168 may individually vertically terminate at a desirable depth from an uppermost boundaries (e.g., an uppermost surfaces) of the insulative line structures 110, such as a vertical depth within a range of from about 30 nm to about 50 nm (e.g., from about 35 nm to about 45 nm, or about 40 nm) from the uppermost boundaries of the insulative line structures 110. The storage node contact openings 168 may individually vertically terminate (e.g., in the Z-direction) above the uppermost boundaries of the word line structures 108, such as between uppermost boundaries and lowermost boundaries of the insulative line structures 110. Each of the storage node contact openings 168 may be formed to exhibit substantially the geometric configuration (e.g., substantially the same dimensions, and substantially same shape) as each other of the storage node contact openings 168, or at least one of the storage node contact openings 168 may be formed to exhibit a different geometric configuration (e.g., different dimension(s) and/or a different shape) than at least one other of the storage node contact openings 168.

The storage node contact openings 168 may be formed using a material removal process employing EUV lithography. EUV lithography may be used to form a desirable pattern for the storage node contact openings 168 in an additional EUV resist material initially formed over the additional mask structure 162, and then the resulting pattern may be transferred into the additional mask structure 162, the third dielectric material 116, the second dielectric material 114, the first dielectric material 112, and the pillar structures 104 using an etching (e.g., ion beam etching) process to form the storage node contact openings 168. Portions of the additional EUV resist material remaining (if any) following the etching process may subsequently be removed.

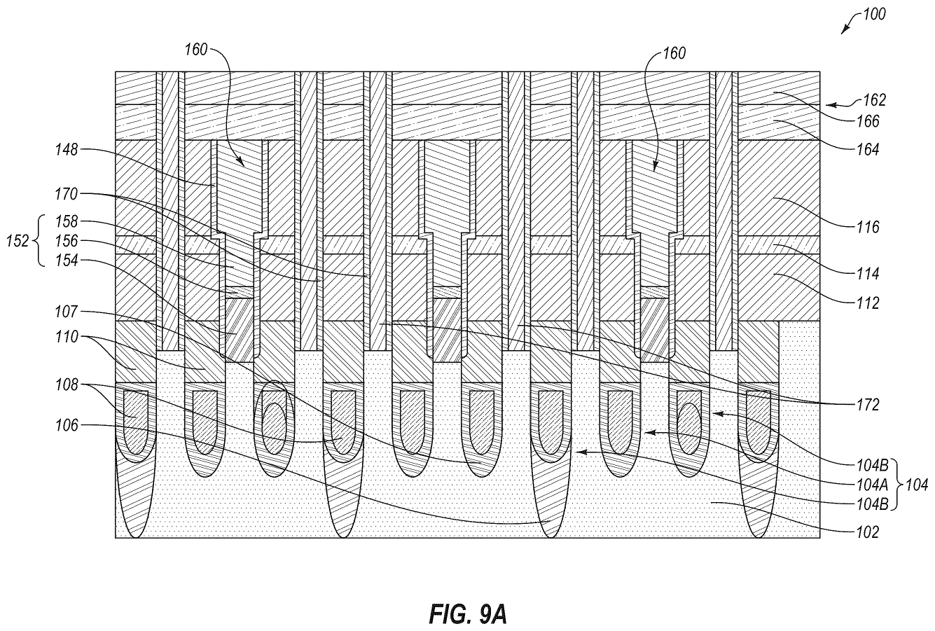

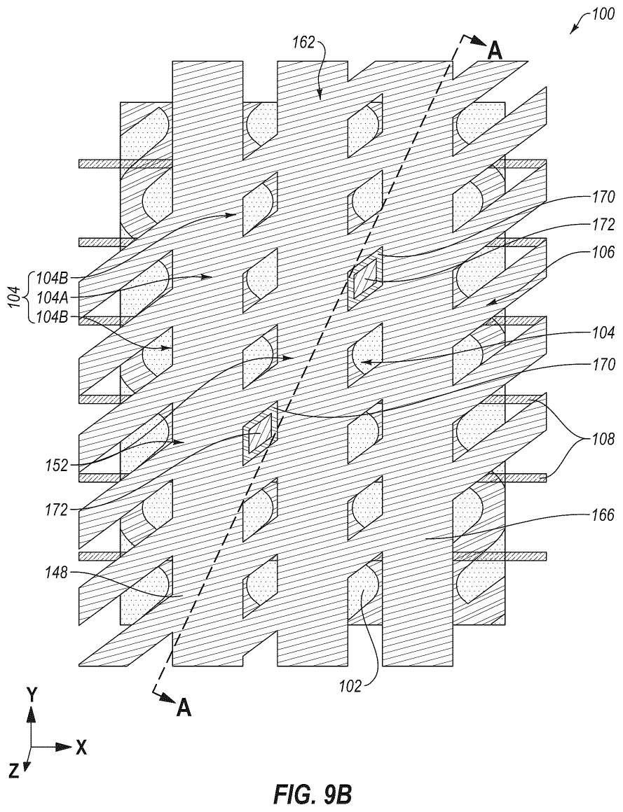

Referring next to FIG. 9A, a second spacer material 170 may be formed (e.g., substantially conformally formed) to extend continuously on or over surfaces of the microelectronic device structure 100 defining the storage node contact openings 168 (FIG. 8A), and portions of at least the second spacer material 170 at bottoms of the storage node contact openings 168 (FIG. 8A) may be removed (e.g., by way of so-called “punch through” etching) to expose the storage node contact regions 104B of the pillar structures 104, and then additional semiconductor material 172 (e.g., additional epitaxial semiconductor material) may be formed to substantially fill remainders of the storage node contact openings 168 (FIG. 8A). FIG. 9B is a top-down view of the microelectronic device structure 100 at the processing stage shown in FIG. 9A, wherein the line A-A corresponds to the longitudinal cross-section of the microelectronic device structure 100 depicted in FIG. 9A. For clarity in understanding the drawings and related description, some features (e.g., structures, materials, regions) of the microelectronic device structure 100 at the processing stage of FIGS. 9A and 9B that are depicted in FIG. 9A are not depicted in FIG. 9B, and vice versa. However, it will be understood that any feature depicted in at least one of FIGS. 9A and 9B may be included in the microelectronic device structure 100 at the processing stage of FIGS. 9A and 9B.

As shown in FIG. 9A, the second spacer material 170 partially (e.g., less than completely) fills the storage node contact openings 168 (FIG. 8A). The second spacer material 170 may substantially completely cover surfaces of the microelectronic device structure 100 defining the storage node contact openings 168 (FIG. 8A). The second spacer material 170 may serve as an isolation material for conductive structures (e.g., storage node contact structures) subsequently formed within horizontal areas of the storage node contact openings 168 (FIG. 8A), as described in further detail below.

The second spacer material 170 may be formed of and include dielectric material. In some embodiments, the second spacer material 170 is formed of and includes a dielectric nitride material (e.g., SiN_{y}, such as Si₃N₄). In additional embodiments, the second spacer material 170 is formed of and includes at least one low-K (low-dielectric constant) dielectric material, such as one or more of silicon oxycarbide (SiOₓC_{y}), silicon oxynitride (SiOₓN_{y}), hydrogenated silicon oxycarbide (SiCₓO_{y}H_{z}), and silicon oxycarbonitride (SiOₓC_{z}N_{y}). In addition, the second spacer material 170 may be formed to have a thickness within a range of from about 1 nm to about 5 nm, such as from about 2 nm to about 4 nm, or from about 2 nm to about 3 nm.

Following the formation of the second spacer material 170, portions thereof at lower boundaries (e.g., bottoms) of the storage node contact openings 168 (FIG. 8A) may be removed, while at least partially (e.g., substantially) maintaining additional portions thereof at side boundaries (e.g., sides) of the storage node contact openings 168 (FIG. 8A). In some embodiments, the removal process also partially removes portions of the pillar structures 104 within horizontal areas of the storage node contact regions 104B. Lowermost boundaries of the resulting extended storage node contact openings may vertically overlie uppermost boundaries of the word line structures 108. For example, the lowermost boundaries of the extended storage node contact openings may be positioned within vertical boundaries (e.g., between uppermost boundaries and lowermost boundaries) of the insulative line structures 110. In some embodiments, the lowermost boundaries of the extended storage node contact openings are vertically offset from (e.g., vertically overlie) the uppermost boundaries of the word line structures 108 by greater than or equal to about 10 nm.

With continued reference to FIG. 9A, the additional semiconductor material 172 may be formed to directly physically contact the storage node contact regions 104B of the pillar structures 104. The additional semiconductor material 172 may at least partially (e.g., substantially) fill portions of the storage node contact openings 168 (FIG. 8A) (or extend storage node contact openings) remaining following the formation and processing (e.g., punch through etch) of the second spacer material 170. In some embodiments, the additional semiconductor material 172 is formed of and includes additional epitaxial semiconductor material, such as additional epitaxial polycrystalline silicon. The additional semiconductor material 172 may be epitaxially grown from semiconductor material of the storage node contact regions 104B of the pillar structures 104 in contact therewith.

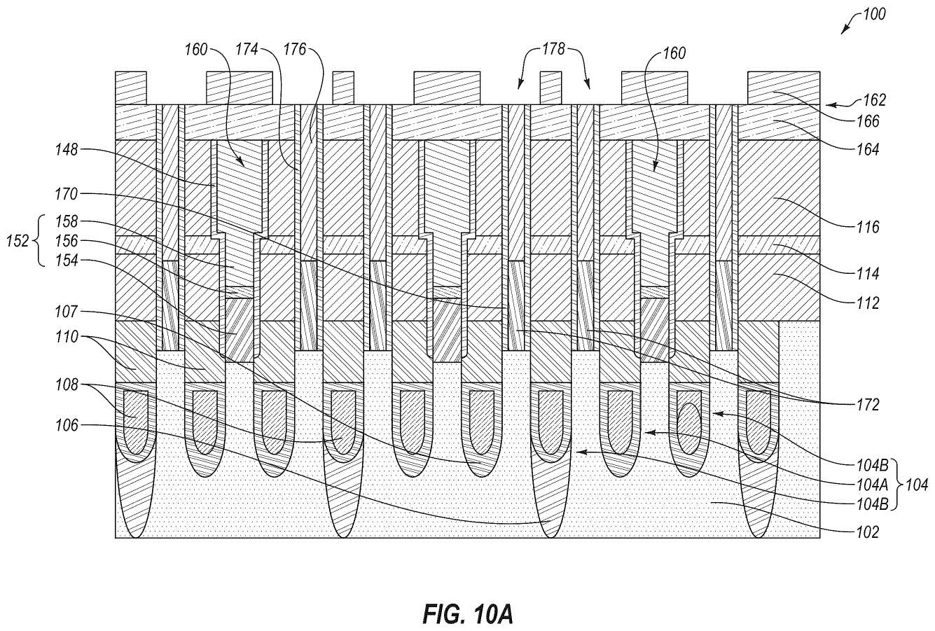

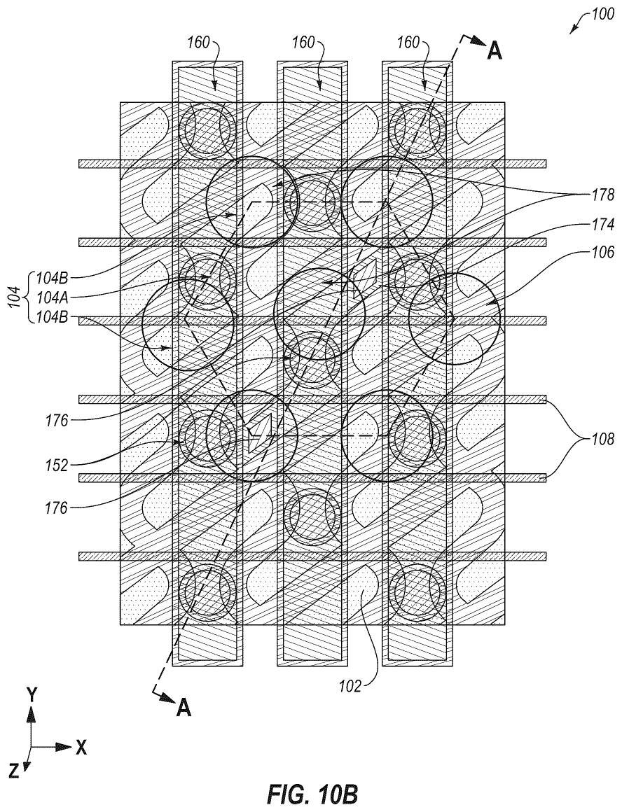

Referring next to FIG. 10A, the additional semiconductor material 172 within the storage node contact openings 168 (FIG. 8A) may be vertically recessed; a third spacer material 174 may be formed (e.g., substantially conformally formed) to extend continuously on or over surfaces of the microelectronic device structure 100 defining newly unfilled portions the storage node contact openings 168 (FIG. 8A); and then second sacrificial structures 176 may be formed over the third spacer material 174 and within the remainders of the storage node contact openings 168 (FIG. 8A). Thereafter, portions of the fifth dielectric material 166, the second sacrificial structures 176, and the third spacer material 174 may be removed to form redistribution layer (RDL) openings 178 vertically extending through the fifth dielectric material 166 and exposing remaining (e.g., unremoved) portions of the second sacrificial structures 176 and the third spacer material 174. FIG. 10B is a top-down view of the microelectronic device structure 100 at the processing stage shown in FIG. 10A, wherein the line A-A corresponds to the longitudinal cross-section of the microelectronic device structure 100 depicted in FIG. 10A. For clarity in understanding the drawings and related description, some features (e.g., structures, materials, regions) of the microelectronic device structure 100 at the processing stage of FIGS. 10A and 10B that are depicted in FIG. 10A are not depicted in FIG. 10B, and vice versa. However, it will be understood that any feature depicted in at least one of FIGS. 10A and 10B may be included in the microelectronic device structure 100 at the processing stage of FIGS. 10A and 10B.

Referring to FIG. 10A, upper portions of the additional semiconductor material 172 formed at the processing stage of FIGS. 9A and 9B may be removed (e.g., through an etching process) to vertically recess the additional semiconductor material 172. Upper boundaries (e.g., upper surfaces) of the remaining portions of the additional semiconductor material 172 may vertically underlie lower boundaries of fourth dielectric material 164. For example, the upper boundaries of the remaining portions of the additional semiconductor material 172 may be vertically positioned at or below lower boundaries of the third dielectric material 116. In some embodiments, the upper boundaries of the remaining portions of the additional semiconductor material 172 are positioned at or below lower boundaries of the second dielectric material 114.

The third spacer material 174 may be formed (e.g., substantially conformally formed) to partially (e.g., less than completely) fill the newly unfilled portions the storage node contact openings 168 (FIG. 8A) resulting from the removal of the upper portions of the additional semiconductor material 172. The third spacer material 174 may substantially cover upper surfaces of the remaining portions of the additional semiconductor material 172 within horizontal areas of the storage node contact openings 168 (FIG. 8A), as well as side surfaces of the microelectronic device structure 100 (e.g., side surfaces of the fifth dielectric material 166, the fourth dielectric material 164, the third dielectric material 116, the second dielectric material 114) defining horizontal boundaries of the newly unfilled portions of the storage node contact openings 168 (FIG. 8A). The third spacer material 174 may protect the remaining portions of the additional semiconductor material 172 and may ensure critical dimension (CD) control during subsequent processing acts (e.g., subsequent cleaning acts).

The third spacer material 174 may be formed of and include dielectric material. In some embodiments, the third spacer material 174 is formed of and includes a dielectric nitride material (e.g., SiN_{y}, such as Si₃N₄). In additional embodiments, the third spacer material 174 is formed of and includes at least one low-K (low-dielectric constant) dielectric material, such as one or more of silicon oxycarbide (SiOₓC_{y}), silicon oxynitride (SiOₓN_{y}), hydrogenated silicon oxycarbide (SiCₓO_{y}H_{z}), and silicon oxycarbonitride (SiOₓC_{z}N_{y}). In addition, the third spacer material 174 may be formed to have a thickness within a range of from about 1 nm to about 5 nm, such as from about 2 nm to about 4 nm, or from about 2 nm to about 3 nm.

Still referring to FIG. 10A, the second sacrificial structures 176 may be formed of and include a sacrificial material that is selectively etchable relative at least to the fifth dielectric material 166, the fourth dielectric material 164, and the third spacer material 174. In some embodiments, the second sacrificial structures 176 are formed of and include a carbon-containing material (e.g., a carbon-based material), such as amorphous carbon. Prior to the formation of the RDL openings 178, upper boundaries (e.g., upper surfaces) of the second sacrificial structures 176 may be formed to be substantially coplanar with an upper boundary (e.g., upper surface) of the fifth dielectric material 166. For example, following the formation of the third spacer material 174, sacrificial material may be formed inside and outside of remainders of the newly unfilled portions the storage node contact openings 168 (FIG. 8A), and then portions of the sacrificial material and the third spacer material 174 overlying the upper boundary of the fifth dielectric material 166 may be removed (e.g., by way of a CMP process) to form the second sacrificial structures 176 and expose the fifth dielectric material 166. Thereafter, the second sacrificial structures 176 may be vertically recessed as a result of the formation of the RDL openings 178, as described in further detail below.

The RDL openings 178 may be formed to facilitate a horizontal pattern (e.g., a horizontal arrangement) for subsequently formed RDL structures and storage node structures (e.g., capacitors) than is different (e.g., at least partially horizontally offset from) a horizontal pattern of the storage node contact structures to subsequently be formed with horizontal areas of the storage node contact openings 168 (FIG. 8A). The subsequently formed RDL structures (and the associated subsequently formed storage node structures) may be coupled to the subsequently formed storage node contact structures, as described in further detail below. The RDL openings 178 may at least partially horizontally overlap the second sacrificial structures 176. However, horizontal centers of at least some of the RDL openings 178 may be offset from horizontal centers of at least some of the second sacrificial structures 176 exposed thereby.

As shown in FIG. 10A, the RDL openings 178 may individually be formed to vertically extend at least through the fifth dielectric material 166. In some embodiments, the lower boundaries (e.g., floors) of the RDL openings 178 may be defined, at least in part, by remaining portions of the fourth dielectric material 164, the third spacer material 174, and the second sacrificial structures 176. In addition, in some embodiments, side boundaries (e.g., horizontal boundaries) of the RDL openings 178 may be defined, at least in part, by remaining portions of the fifth dielectric material 166.

Referring to FIG. 10B, the microelectronic device structure 100 may be formed to includes a hexagonal pattern (e.g., a hexagonal arrangement, a hexagonal grid, a hexagonal array) of the RDL openings 178. The hexagonal pattern may exhibits a repeating horizontal arrangement of seven (7) RDL openings 178, wherein one (1) of the seven (7) RDL openings 178 is substantially horizontally centered between six (6) other of the seven (7) RDL openings 178. The hexagonal pattern exhibits different three (3) axes of symmetry (e.g., a first axis of symmetry, a second axis of symmetry, and a third axis of symmetry) in the same horizontal plane (e.g., the XY plane) about a center of the horizontally centered RDL opening 178 of the seven (7) RDL openings 178. Different axes of symmetry directly radially adjacent to one another may be radially separated from one another by an angle of about 60 degrees. The hexagonal pattern of the RDL openings 178 exhibits a smaller horizontal area relative to a conventional square pattern having the same type and quantity of openings.

The geometric configurations (e.g., shapes, dimensions) and spacing of each of the RDL openings 178 may at least partially depend upon the geometric configurations (e.g., shapes, dimensions) and spacing of the second sacrificial structures 176 exposed thereby. For example, the RDL openings 178 may individually be formed to exhibit a generally columnar shape (e.g., a circular column shape, a rectangular column shape). In some embodiments, each of the RDL openings 178 is formed to exhibit a circular column shape having substantially circular horizontal cross-sectional shape.

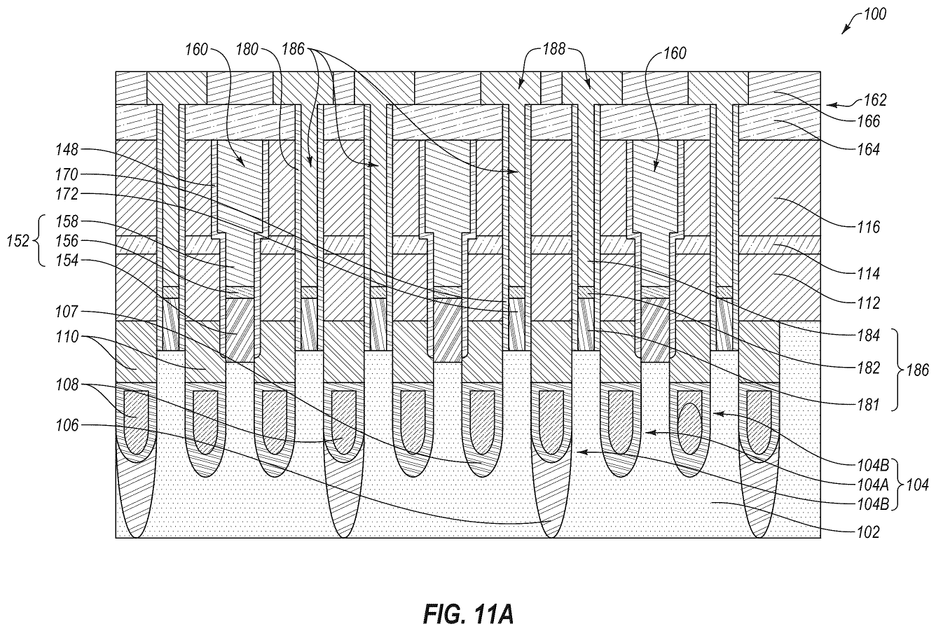

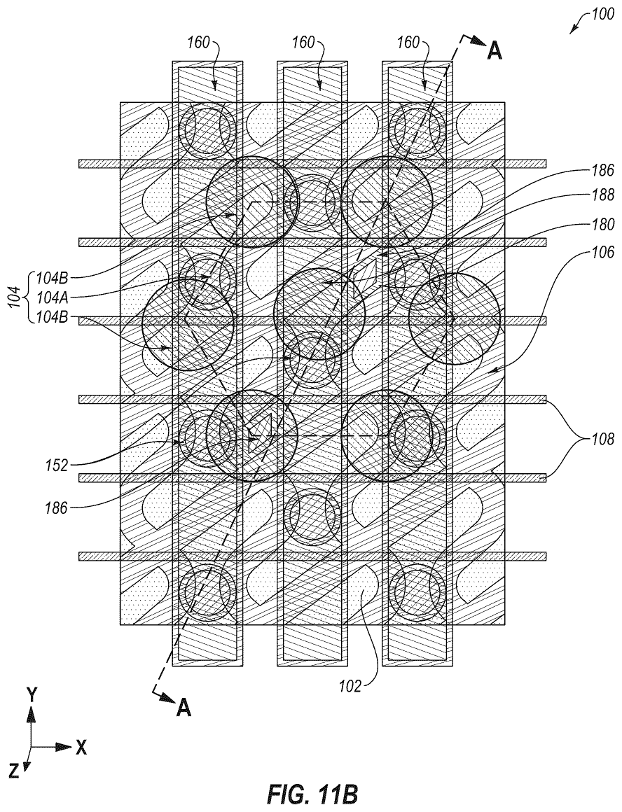

Referring next to FIG. 11A, remaining portions of the second sacrificial structures 176 (FIG. 10A) may be removed (e.g., through a stripping and cleaning process), and portions of the third spacer material 174 on upper surfaces of the remaining portions of the additional semiconductor material 172 may be removed (e.g., by way of so-called “punch through” etching) to form storage node contact spacer structures 180. Thereafter, the formation of storage node contact structures 186 may be completed within the horizontal areas of the storage node contact openings 168 (FIG. 8A), and RDL structures 188 may be formed over the storage node contact structures 186 and within the RDL openings 178 (FIG. 10A). An individual RDL structure 188 may be integral and continuous (e.g., unitary) with an individual storage node contact structure 186. FIG. 11B is a top-down view of the microelectronic device structure 100 at the processing stage shown in FIG. 11A, wherein the line A-A corresponds to the longitudinal cross-section of the microelectronic device structure 100 depicted in FIG. 11A. For clarity in understanding the drawings and related description, some features (e.g., structures, materials, regions) of the microelectronic device structure 100 at the processing stage of FIGS. 11A and 11B that are depicted in FIG. 11A are not depicted in FIG. 11B, and vice versa. However, it will be understood that any feature depicted in at least one of FIGS. 11A and 11B may be included in the microelectronic device structure 100 at the processing stage of FIGS. 11A and 11B.

Referring to FIG. 11A, the storage node contact structures 186 may individually be formed to include a first portion 181 (e.g., a lower portion) vertically overlying one of the storage node contact regions 104B of an individual pillar structure 104; a second portion 182 (e.g., a middle portion) vertically overlying the first portion 181; and a third portion 184 (e.g., an upper portion) vertically overlying the second portion 182. The first portion 181 may directly physically contact the storage node contact region 104B of the pillar structure 104, the third portion 184 may directly physically contact an individual RDL structure 188, and the second portion 182 may vertically extend from and between the first portion 181 and the third portion 184.

The first portion 181 of an individual storage node contact structure 186 may be formed of and include a remaining portion of the additional semiconductor material 172 (e.g., epitaxial semiconductor material, such as epitaxial polycrystalline silicon) within a horizontal area of an individual storage node contact opening 168 (FIG. 8A). For an individual storage node contact structure 186, an upper boundary of the first portion 181 thereof may be vertically positioned below, at, or above the uppermost boundaries of the insulative line structures 110. In some embodiments, upper boundaries of the first portions 181 of the storage node contact structures 186 are vertically positioned at or above the uppermost boundaries of the insulative line structures 110. For example, the upper boundaries of the first portions 181 of the storage node contact structure 186 may vertically positioned between a lowermost boundary and an uppermost boundary of the first dielectric material 112.

The second portion 182 of an individual storage node contact structure 186 may be formed of and include metal silicide material, such as one or more of cobalt silicide (CoSiₓ), tungsten silicide (WSiₓ), tantalum silicide (TaSiₓ), molybdenum silicide (MoSiₓ), nickel silicide (NiSiₓ), and titanium silicide (TiSiₓ). For an individual storage node contact structure 186, an upper boundary of the second portion 182 thereof may be vertically positioned below a lowermost boundary of the second dielectric material 114, such as between the lowermost boundary of the second dielectric material 114 and the uppermost boundaries of the insulative line structures 110.

The third portion 184 of an individual storage node contact structure 186 may be formed of and include conductive material, such as one or more of at least one elemental metal (e.g., W, Ti, Mo, Nb, V, Hf, Ta, Cr, Zr, Fe, Ru, Os, Co, Rh, Ir, Ni, Pd, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), and a conductive metal-containing material (e.g., a conductive metal nitride, a conductive metal carbide, a conductive metal oxide). In some embodiments, the third portion 184 is formed of and includes elemental metal, such as one or more of Ru, Mo, Ti, and W. For an individual storage node contact structure 186, an upper boundary of the third portion 184 thereof may be vertically positioned above an uppermost boundary of the third dielectric material 116 and at or below a lowermost boundary of the fifth dielectric material 166.

Still referring to FIG. 11A, the RDL structures 188 may substantially fill portions of the RDL openings 178 (FIGS. 10A and 10B). A geometric configuration (e.g., shape, dimensions) of an individual RDL structure 188 may substantially correspond to a geometric configuration of the RDL opening 178 (FIGS. 10A and 10B) within which the RDL structure 188 is formed.

The RDL structures 188 may individually be formed of and include conductive material, such as one or more of at least one elemental metal (e.g., W, Ti, Mo, Nb, V, Hf, Ta, Cr, Zr, Fe, Ru, Os, Co, Rh, Ir, Ni, Pd, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), and a conductive metal-containing material (e.g., a conductive metal nitride, a conductive metal carbide, a conductive metal oxide). A material composition of the RDL structures 188 may be substantially the same as a material composition of the third portions 184 of the storage node contact structure 186. In some embodiments, the RDL structures 188 are individually formed of and include elemental metal, such as one or more of Ru, Mo, Ti, and W. As shown in FIG. 7A, for an individual RDL structure 188, an upper boundary thereof may be formed to be substantially coplanar with an uppermost boundary of the fifth dielectric material 166.

To form the storage node contact structures 186 and the RDL structures 188, after forming the storage node contact spacer structures 180, conductive material may be formed inside and outside of newly unfilled portions of the storage node contact openings 168 (FIG. 8A) and the RDL openings 178 (FIGS. 10A and 10B), and subjected to thermal processing (e.g., rapid thermal processing (RTP)) to form the second portions 182 of the storage node contact structures 186. A wet cleaning process may then be performed, followed by the formation of additional conductive material inside and outside of new remainders of the storage node contact openings 168 (FIG. 8A) and the RDL openings 178 (FIGS. 10A and 10B) to form the third portions 184 of the storage node contact structures 186. Thereafter portions of the conductive material (if any) and the additional conductive material overlying an uppermost boundary (e.g., an uppermost surface) of the fifth dielectric material 166 may be removed (e.g., by way of a CMP process) to expose the fifth dielectric material 166 and form the RDL structures 188.

Following the processing stage described with reference to FIGS. 11A and 11B, the microelectronic device structure 100 may be subjected to additional processing, as desired. For example, storage node structures (e.g., capacitor structures) may be formed vertically over and in electrical communication with the RDL structures 188. Such additional processing may employ conventional processes and conventional processing equipment, and therefore is not described in detail herein.

Thus, in accordance with embodiments of the disclosure, a method of forming a microelectronic device includes forming a first dielectric stack over a semiconductor base structure including pillar structures separated from one another by filled isolation trenches. Digit line contacts are formed to partially vertically extend through the first dielectric stack and into digit line contact regions of the pillar structures. Digit lines are formed over and in contact with the digit line contacts, the digit lines partially vertically extending through the first dielectric stack. A second dielectric stack is formed over the digit lines and the first dielectric stack. Storage node contacts are formed to vertically extend partially through the second dielectric stack, completely through the first dielectric stack, and into storage node contact regions of the pillar structures. RDL structures are formed over and in contact with the storage node contacts, the RDL structures partially vertically extending through the second dielectric stack.

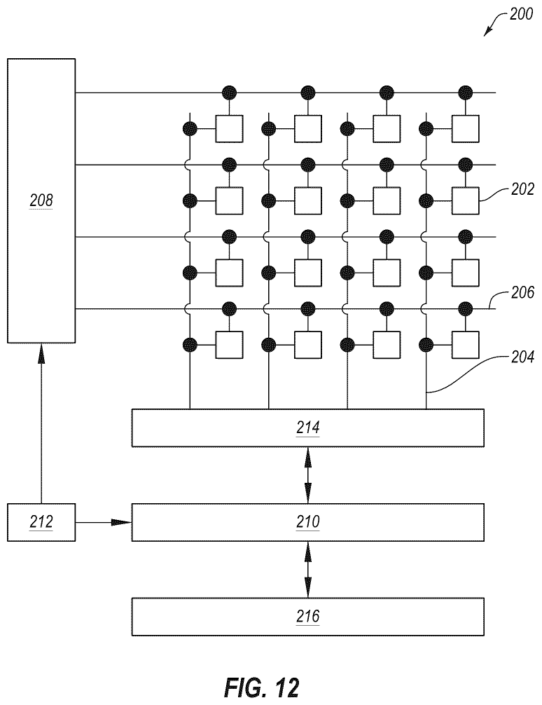

Microelectronic device structures (e.g., the microelectronic device structure 100 at or following the processing stage previously described with reference to FIGS. 11A and 11B) of the disclosure may be included in microelectronic devices of the disclosure. As a non-limiting example, FIG. 12 illustrates a functional block diagram of a memory device 200, in accordance with an embodiment of the disclosure. The memory device 200 may include, for example, an embodiment of the microelectronic device structure 100 at or following the processing stage previously described with reference to FIGS. 11A and 11B. As shown in FIG. 12, the memory device 200 may include memory cells 202, digit lines 204, word lines 206, a row decoder 208, a column decoder 210, a memory controller 212, a sense device 214, and an input/output device 216.

The memory cells 202 of the memory device 200 are programmable to at least two different logic states (e.g., logic 0 and logic 1). Each memory cell 202 may individually include a capacitor and transistor (e.g., a pass transistor). The transistors may be defined, in part, by the pillar structures 104 (FIGS. 11A and 11B) and the word line structures 108 (FIGS. 11A and 11B) (e.g., serving as gate electrodes) previously describe herein with reference to FIGS. 1A through 11B. The capacitor stores a charge representative of the programmable logic state (e.g., a charged capacitor may represent a first logic state, such as a logic 1; and an uncharged capacitor may represent a second logic state, such as a logic 0) of the memory cell 202. The transistor grants access to the capacitor upon application (e.g., by way of one of the word lines 206) of a minimum threshold voltage to a semiconductive channel thereof for operations (e.g., reading, writing, rewriting) on the capacitor.

The digit lines 204 (e.g., corresponding to the digit line structures 160 (FIGS. 11A and 11B)) are connected to the capacitors of the memory cells 202 by way of the transistors of the memory cells 202. The word lines 206 (e.g., corresponding to the word line structures 108 (FIGS. 11A and 11B)) extend perpendicular to the digit lines 204, and serve as gates of the transistors of the memory cells 202. Operations may be performed on the memory cells 202 by activating appropriate digit lines 204 and word lines 206. Activating a digit line 204 or a word line 206 may include applying a voltage potential to the digit line 204 or the word line 206. Each column of memory cells 202 may individually be connected to one of the digit lines 204, and each row of the memory cells 202 may individually be connected to one of the word lines 206. Individual memory cells 202 may be addressed and accessed through the intersections (e.g., cross points) of the digit lines 204 and the word lines 206.

The memory controller 212 may control the operations of memory cells 202 through various components, including the row decoder 208, the column decoder 210, and the sense device 214 (e.g., local I/O device). The memory controller 212 may generate row address signals that are directed to the row decoder 208 to activate (e.g., apply a voltage potential to) predetermined word lines 206, and may generate column address signals that are directed to the column decoder 210 to activate (e.g., apply a voltage potential to) predetermined digit lines 204. The sense device 214 may include sense amplifiers configured and operated to receive digit line inputs from the digit lines selected by the column decoder 210 and to generate digital data values during read operations. The memory controller 212 may also generate and control various voltage potentials employed during the operation of the memory device 200. In general, the amplitude, shape, and/or duration of an applied voltage may be adjusted (e.g., varied), and may be different for various operations of the memory device 200.

During use and operation of the memory device 200, after being accessed, a memory cell 202 may be read (e.g., sensed) by the sense device 214. The sense device 214 may compare a signal (e.g., a voltage) of an appropriate digit line 204 to a reference signal in order to determine the logic state of the memory cell 202. If, for example, the digit line 204 has a higher voltage than the reference voltage, the sense device 214 may determine that the stored logic state of the memory cell 202 is a logic 1, and vice versa. The sense device 214 may include transistors and amplifiers to detect and amplify a difference in the signals (commonly referred to in the art as “latching”). The detected logic state of a memory cell 202 may be output through the column decoder 210 to the input/output device 216. In addition, a memory cell 202 may be set (e.g., written) by similarly activating an appropriate word line 206 and an appropriate digit line 204 of the memory device 200. By controlling the digit line 204 while the word line 206 is activated, the memory cell 202 may be set (e.g., a logic value may be stored in the memory cell 202). The column decoder 210 may accept data from the input/output device 216 to be written to the memory cells 202. Furthermore, a memory cell 202 may also be refreshed (e.g., recharged) by reading the memory cell 202. The read operation will place the contents of the memory cell 202 on the appropriate digit line 204, which is then pulled up to full level (e.g., full charge or discharge) by the sense device 214. When the word line 206 associated with the memory cell 202 is deactivated, all of memory cells 202 in the row associated with the word line 206 are restored to full charge or discharge.

Thus, in accordance with embodiments of the disclosure, a microelectronic device includes semiconductor base structure, word lines, a first dielectric stack, digit line contacts, digit lines, a second dielectric stack, storage node contacts, and redistribution layer structures. The semiconductor base structure includes pillar structures horizontally separated from one another by filled isolation trenches. The word lines horizontally extend through the pillar structures and the filled isolation trenches in a first direction. The first dielectric stack vertically overlies the pillar structures, the filled isolation trenches, and the word lines. The digit line contacts partially vertically extend through the first dielectric stack and into digit line contact regions of the pillar structures. The digit lines are over and in contact with the digit line contacts and partially vertically extend through the first dielectric stack, the digit lines horizontally extend in a second direction orthogonal to the first direction. The second dielectric stack overlies the digit lines and the first dielectric stack. The storage node contacts vertically extend partially through the second dielectric stack, completely through the first dielectric stack, and into storage node contact regions of the pillar structures. The redistribution layer structures overlie and are in contact with the storage node contacts, the redistribution layer structures partially vertically extend through the second dielectric stack.

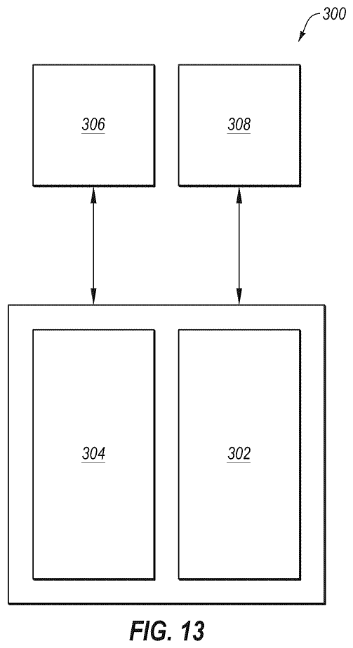

Microelectronic devices (e.g., the memory device 200 shown in FIG. 12) including microelectronic device structures (e.g., the microelectronic device structure 100 shown in FIGS. 11A and 11B) in accordance with embodiments of the disclosure may be used in embodiments of electronic systems of the disclosure. For example, FIG. 13 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, an embodiment of a microelectronic device (e.g., the memory device 200 shown in FIG. 12) previously described herein. The electronic system 300 may further include at least one electronic signal processor device 304 (often referred to as a “microprocessor”). The electronic signal processor device 304 may, optionally, include an embodiment a microelectronic device (e.g., the memory device 200 shown in FIG. 12) previously described herein. While the memory device 302 and the electronic signal processor device 304 are depicted as two (2) separate devices in FIG. 13, in additional embodiments, a single (e.g., only one) memory/processor device having the functionalities of the memory device 302 and the electronic signal processor device 304 is included in the electronic system 300. In such embodiments, the memory/processor device may include an embodiment of a microelectronic device structure (e.g., the microelectronic device structure 100 shown in FIGS. 11A and 11B) previously described herein, and/or an embodiment of a microelectronic device (e.g., the memory device 200 shown in FIG. 12) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

Thus, in accordance with embodiments of the disclosure, an electronic system includes an input device, an output device, a processor device operably coupled to the input device and the output device, and a memory device operably coupled to the processor device and including at least one microelectronic device structure. The at least one microelectronic device structure includes a base structure, word lines, dielectric materials, digit line contacts, digit lines, additional dielectric materials, storage node contacts, and redistribution layer structures. The base structure includes semiconductive pillar structures horizontally separated from one another by filled isolation trenches. The word lines extend through the semiconductive pillar structures and the filled isolation trenches in a first horizontal direction. The dielectric materials over the pillar structures, the filled isolation trenches, and the word lines. The digit line contacts extend through a lower portion of the dielectric materials and into digit line contact regions of the semiconductive pillar structures. The digit lines are over and in contact with the digit line contacts and vertically extend through an upper portion of the dielectric materials. The digit lines extend in a second horizontal direction orthogonal to the first horizontal direction. The additional dielectric materials overlie the digit lines and the dielectric materials. The storage node contacts vertically extend through a lower portion of the additional dielectric materials, completely through the dielectric materials, and into storage node contact regions of the semiconductive pillar structures. The redistribution layer structures are over and in contact with the storage node contacts. The redistribution layer structures vertically extend through an upper portion the additional dielectric materials.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A method of forming a microelectronic device, comprising:
forming a first dielectric stack over a semiconductor base structure comprising pillar structures separated from one another by filled isolation trenches;
forming digit line contacts partially vertically extending through the first dielectric stack and into digit line contact regions of the pillar structures;
forming digit lines over and in contact with the digit line contacts, the digit lines partially vertically extending through the first dielectric stack;
forming a second dielectric stack over the digit lines and the first dielectric stack;
forming storage node contacts vertically extending partially through the second dielectric stack, completely through the first dielectric stack, and into storage node contact regions of the pillar structures; and
forming redistribution layer (RDL) structures over and in contact with the storage node contacts, the RDL structures partially vertically extending through the second dielectric stack.

2. The method of claim 1, wherein forming a first dielectric stack comprises forming the first dielectric stack to comprise:
a first dielectric oxide material over the pillar structures and the filled isolation trenches;
a first dielectric nitride material over the first dielectric oxide material; and
a second dielectric oxide material over the first dielectric nitride material.

3. The method of claim 1, further comprising:
forming first sacrificial structures vertically extending completely through the first dielectric stack into digit line contact regions of the pillar structures;
removing upper portions of the first sacrificial structures and the first dielectric stack to form digit line trenches horizontally extending through the first dielectric stack;
removing remaining portions of the first sacrificial structures exposed by the digit line trenches to form digit line contact openings;
forming the digit line contacts in the digit line contact openings; and
forming the digit lines in the digit line trenches.

4. The method of claim 3, wherein forming first sacrificial structures comprises:
forming a first hardmask structure over the first dielectric stack, the first hardmask structure comprising:
a first underlayer (UL) material over the first dielectric stack;
a first developable anti-reflective coating (DARC) material over the first UL material;
a first resist adhesion layer (RAL) material over the first DARC material; and
a first extreme ultraviolet (EUV) resist material over the first RAL material;
forming first openings vertically extending completely through the first hardmask structure and the first dielectric stack and into the digit line contact regions of the pillar structures using a first material removal process employing EUV lithography;
filling the first openings with first sacrificial material; and
removing the first hardmask structure and upper portions of the first sacrificial material to form the first sacrificial structures.

5. The method of claim 4, wherein removing upper portions of the first sacrificial structures and the first dielectric stack comprises:
forming a second hardmask structure over the first sacrificial structures and the first dielectric stack, the second hardmask structure comprising:
a second UL material over the first sacrificial structures and the first dielectric stack;
a second DARC material over the second UL material;
a second RAL material over the second DARC material; and
a second EUV resist material over the second RAL material;
forming linear mask openings vertically extending completely through the second hardmask structure and to the first sacrificial structures and the first dielectric stack using a second material removal process employing additional EUV lithography; and
extending a pattern of the linear mask openings within the second hardmask structure into the first dielectric stack and the first sacrificial structures to form the digit line trenches.

6. The method of claim 5, wherein forming the digit line contacts in the digit line contact openings comprises:
forming a first spacer material to partially fill the digit line contact openings and the digit line trenches;
removing portions of the first spacer material at bottoms of the digit line contact openings to expose semiconductor material of the digit line contact regions of the pillar structures;
growing epitaxial semiconductor material within lower portions of the digit line contact openings using the semiconductor material of the digit line contact regions of the pillar structures;
forming metal silicide material over the epitaxial semiconductor material and within the digit line contact openings; and
forming conductive material over the metal silicide material and substantially filling remaining portions of the digit line contact openings.

7. The method of claim 6, wherein forming the digit lines in the digit line trenches comprises:
forming an additional amount of the conductive material inside and outside of the digit line trenches, the additional amount of the conductive material substantially filling the digit line trenches; and
removing a portion of the additional amount of the conductive material overlying upper boundaries of the first dielectric stack, remaining portions of the additional amount of the conductive material within the digit line trenches forming the digit lines.

8. The method of claim 1, wherein forming a second dielectric stack over the digit lines and the first dielectric stack comprises:
forming a first dielectric nitride material over the digit lines and the first dielectric stack using a first deposition process; and
forming a second dielectric nitride material over the first dielectric nitride material using a second deposition process, the first deposition process employing relatively lower temperatures than the second deposition process.

9. The method of claim 8, wherein forming storage node contacts comprises:
forming storage node contact openings vertically completely through the second dielectric stack and the first dielectric stack and into storage node contact regions of the pillar structures;
forming first dielectric spacer structures continuously vertically extending along horizontal boundaries of the storage node contact openings;
growing epitaxial semiconductor material within the storage node contact openings and horizontally surrounded by the first dielectric spacer structures using semiconductor material of the storage node contact regions of the pillar structures;
removing portions of the second dielectric nitride material and the epitaxial semiconductor material to form RDL openings, the RDL openings overlying the first dielectric nitride material;
removing upper portions of the epitaxial semiconductor material within upper regions of the storage node contact openings after forming RDL openings;
forming second dielectric spacer structures over remaining portions of the epitaxial semiconductor material and within the upper regions of the storage node contact openings;
forming metal silicide material within the upper regions of the storage node contact openings and horizontally surrounded by the second dielectric spacer structures; and
forming conductive material over the metal silicide material and substantially filling remainders of the upper regions of the storage node contact openings.

10. The method of claim 9, wherein forming RDL structures over and in contact with the storage node contacts comprises:
forming an additional amount of the conductive material inside and outside of the RDL openings, the additional amount of the conductive material substantially filling the RDL openings; and
removing a portion of the additional amount of the conductive material overlying upper boundaries of the second dielectric stack, remaining portions of the additional amount of the conductive material within the RDL openings forming RDL structures.

11. The method of claim 9, wherein forming first dielectric spacer structures comprises:
substantially conformally forming a first dielectric spacer material within the storage node contact openings; and
removing portions of the first dielectric spacer material at bottoms of the storage node contact openings to expose the semiconductor material of the storage node contact regions of the pillar structures.

12. The method of claim 11, wherein forming second dielectric spacer structures comprises:
substantially conformally forming a second dielectric spacer material within the upper regions of the storage node contact openings; and
removing portions of the second dielectric spacer material at bottoms of the upper regions of the storage node contact openings to expose the remaining portions of the epitaxial semiconductor material.

13. The method of claim 1, further comprising forming additional filled trenches vertically extending into the pillar structures and the filled isolation trenches before forming the first dielectric stack, the additional filled trenches comprising:
word lines;
dielectric material horizontally interposed the word lines and semiconductor material of the pillar structures; and
insulative line structures vertically overlying and substantially continuously horizontally extending across the word lines.

14. The method of claim 13, further comprising:
forming lower boundaries of the digit line contacts to vertically overlie upper boundaries of the word lines; and
forming lower boundaries of the storage node contacts to vertically overlie the upper boundaries of the word lines.

15. The method of claim 14, further comprising:
forming the lower boundaries of the digit line contacts to vertically underlie upper boundaries of the insulative line structures, the lower boundaries of the digit line contacts vertically offset from the upper boundaries of the word lines by at least 10 nanometers (nm); and
forming the lower boundaries of the storage node contacts to vertically underlie the upper boundaries of the insulative line structures, the lower boundaries of the storage node contacts vertically offset from the upper boundaries of the word lines by at least 10 nm.

16. A microelectronic device, comprising:
a semiconductor base structure comprising pillar structures horizontally separated from one another by filled isolation trenches;
word lines horizontally extending through the pillar structures and the filled isolation trenches in a first direction;
a first dielectric stack vertically overlying the pillar structures, the filled isolation trenches, and the word lines;
digit line contacts partially vertically extending through the first dielectric stack and into digit line contact regions of the pillar structures;
digit lines over and in contact with the digit line contacts and partially vertically extending through the first dielectric stack, the digit lines horizontally extending in a second direction orthogonal to the first direction;
a second dielectric stack over the digit lines and the first dielectric stack;
storage node contacts vertically extending partially through the second dielectric stack, completely through the first dielectric stack, and into storage node contact regions of the pillar structures; and
redistribution layer (RDL) structures over and in contact with the storage node contacts, the RDL structures partially vertically extending through the second dielectric stack.

17. The microelectronic device of claim 16, wherein lower surfaces of the digit line contacts and the storage node contacts individually vertically overlie upper surfaces of the word lines by at least 10 nanometers (nm).

18. The microelectronic device of claim 16, wherein each of the digit line contacts and each of the storage node contacts individually comprise:
a lower region comprising epitaxial semiconductor material;
an upper region comprising metal material; and
a middle region vertically interposed between the lower region and the upper region and comprising metal silicide material.

19. The microelectronic device of claim 18, wherein:
the digit lines are integral and continuous with the digit line contacts; and
the RDL structures are integral and continuous with the storage node contacts.

20. The microelectronic device of claim 16, wherein:
the digit lines and the digit line contacts each comprise substantially the same conductive material; and
the digit line contacts are unitary with the digit lines.

21. The microelectronic device of claim 16, wherein a maximum horizontal dimension of one of the digit line contacts in the first direction is less than or equal to a maximum horizontal dimension of one of the digit lines in the first direction.

22. The microelectronic device of claim 16, wherein the second dielectric stack comprises:
a first dielectric material over the digit lines and the first dielectric stack; and
a second dielectric material over the first dielectric material.

23. The microelectronic device of claim 16, wherein the storage node contacts each have an elongate horizontal cross-sectional shape.

24. The microelectronic device of claim 16, wherein at least some of the storage node contacts individually have a parallelogram horizontal cross-sectional shape.

25. An electronic system, comprising:
an input device;
an output device;
a processor device operably coupled to the input device and the output device; and
a memory device operably coupled to the processor device and comprising at least one microelectronic device structure comprising:
a base structure comprising semiconductive pillar structures horizontally separated from one another by filled isolation trenches;
word lines extending through the semiconductive pillar structures and the filled isolation trenches in a first horizontal direction;
dielectric materials overlying the pillar structures, the filled isolation trenches, and the word lines;
digit line contacts extending through a lower portion of the dielectric materials and into digit line contact regions of the semiconductive pillar structures;
digit lines over and in contact with the digit line contacts and vertically extending through an upper portion of the dielectric materials, the digit lines extending in a second horizontal direction orthogonal to the first horizontal direction;
additional dielectric materials over the digit lines and the dielectric materials;
storage node contacts vertically extending through a lower portion of the additional dielectric materials, completely through the dielectric materials, and into storage node contact regions of the semiconductive pillar structures; and
redistribution layer (RDL) structures over and in contact with the storage node contacts, the RDL structures vertically extending through an upper portion the additional dielectric materials.
